(19) United States
(12) Patent Application Publication
(10) Pub. No.: US 2011/0286487 A1
(43) Pub. Date: Nov. 24, 2011

(54) SEMICONDUCTOR LASER DEVICE

(76) Inventors: Hitoshi Sato, Okayama (JP); Toru Takayama, Hyogo (JP); Atsushi Higuchi, Kyoto (JP); Masatoshi Sasaki, Okayama (JP); Isao Kidoguchi, Hyogo (JP)

(21) Appl. No.: 13/109,512

(22) Filed: May 17, 2011

(30) Foreign Application Priority Data
May 20, 2010 (JP) 2010-116059

(51) Int. Cl. H01S 5/343

(52) U.S. Cl. 372/45.011

(57) ABSTRACT

A semiconductor laser device includes, on an n-type GaAs substrate, an n-type GaAs contact layer, an n-type first quantum well heterobarrier layer, an n-type AlGaInP cladding layer, a strained quantum well active layer (a first guide layer, GaInP well layers, AlGaInP barrier layers, and a second guide layer), a p-type AlGaInP cladding layer, a p-type GaInP intermediate layer, and a p-type GaAs contact layer, which are formed in this stated order. The semiconductor laser device can perform high-temperature and high-power operation at a lower operating voltage.

### CROSS-REFERENCE TO RELATED APPLICATION

This application claims priority to Japanese Patent Application No. 2010-116059 filed on May 20, 2010, the disclosure of which including the specification, the drawings, and the claims is hereby incorporated by reference in its entirety.

### BACKGROUND

The present disclosure relates to semiconductor laser devices, and more particularly, to semiconductor laser devices with a low operating voltage which are suitable for high-temperature and high-power operation.

Semiconductor laser devices (hereinafter referred to as semiconductor lasers) are widely used in a variety of fields. For example, AlGaAs semiconductor lasers can emit infrared laser light in the 780-nm wavelength band, and AlGaInP semiconductor lasers can emit red laser light in the 650-nm wavelength band. Therefore, these semiconductor lasers are widely used as light sources in the fields of optical disk systems (the former for CDs and the latter for DVDs).

In recent years, as the capacity of optical disk systems has been increased, Blu-ray (BD) optical disk systems with a greater storage capacity than that of CDs or DVDs have come onto the market, and nitride semiconductor lasers which can emit blue-violet laser light in the 405-nm wavelength band have been commercialized.

In this situation, semiconductor lasers used as light sources for optical disk systems are strongly required to perform high-power operation which is needed to increase the recording speed, and higher-temperature operation at 85° C. or more. High-power semiconductor lasers used as light sources for optical disk systems in which data can be recorded and reproduced are required to perform high-temperature and high-power operation in any of the wavelength bands.

Among the significant factors which inhibit the high-temperature and high-power operation is the increase of the operating voltage. The increase of the operating voltage causes an increase in operating power for the device, leading to an increase in temperature due to Joule heat. As a result, the operating current further increases, and therefore, the operating voltage increases, so that the reliability of the device is reduced, which is a serious problem. Because there is also an upper limit of the drive voltage of a drive circuit for driving the semiconductor laser, the increase of the operating voltage is a crucial problem faced when attempting to guarantee the reliability, and the operation and control of the drive circuit.

Here, the increase of the operating voltage will be described using an AlGaInP red laser as an example. A typical AlGaInP semiconductor laser includes an n-type GaAs buffer layer, an n-type AlGaInP cladding layer, an active layer, a p-type AlGaInP cladding layer, and a p-type GaAs contact layer with a small forbidden band energy (band gap energy), which are successively formed on an n-type GaAs substrate.

The reason why the p-type GaAs contact layer is formed on the p-type AlGaInP cladding layer is that when an electrode is formed on p-type GaAs, whose band gap energy is smaller than that of the p-type AlGaInP cladding layer, a lower contact resistance is obtained between the metal electrode and the p-type GaAs contact layer.

In this structure, AlGaInP and GaAs have different band gap energies. Therefore, for example, as shown in FIG. 1, the difference in band gap energy causes a potential barrier (heterospike) ΔEᵥ at an interface between the p-type AlGaInP cladding layer and the p-type GaAs contact layer. This is a potential barrier which impedes the injection of holes into the p-type cladding layer. Therefore, it is necessary to increase an applied voltage required to inject holes into the p-type cladding layer, resulting in an increase in the operating voltage of the device.

Also, as shown in FIG. 2, a heterospike ΔEᵥ is also formed at an interface between the n-type GaAs buffer layer and the n-type AlGaInP cladding layer. This is a potential barrier which impedes the injection of electrons injected from the n-type GaAs substrate into the n-type AlGaInP cladding layer.

As shown in FIG. 3, the red semiconductor laser typically includes, between the p-type AlGaInP cladding layer and the p-type GaAs contact layer, an intermediate layer made of p-type GaInP whose band gap energy is between the magnitude of the band gap energy of the p-type AlGaInP cladding layer and the magnitude of the band gap energy of the p-type GaAs contact layer. In this case, the magnitude of the heterospike is divided into two, so that the resultant heterospike divisions have smaller magnitudes (ΔEᵥ₁ and ΔEᵥ₂), and therefore, the influence on the operating voltage is reduced.

The atomic compositions of AlGaInP materials which are lattice matched to GaAs are represented by (AlₓGa₁₋ₓ)_{0.51}In_{0.49}P (0≦x≦1). In this case, the band gap energy of GaInP where the mole fraction of Al is zero is 1.91 eV. The band gap energy of (Al_{0.7}Ga_{0.3})_{0.51}In_{0.49}P where the mole fraction of Al is 0.7, which is typically used for cladding layers, is 2.32 eV. The band gap energy of GaAs is 1.42 eV.

When a p-type GaAs layer and a p-type (Al_{0.7}Ga_{0.3})_{0.51}In_{0.49}P layer are joined together, a heterospike of about 0.7 eV occurs in the valence band. When GaAs and GaInP are joined together, a heterospike of about 0.5 eV (ΔEᵥ in FIG. 1) occurs in the valence band. Therefore, by providing the p-type GaInP intermediate layer, the magnitude of each heterobarrier occurring in the valence band is reduced. However, the heterobarrier having a magnitude of about 0.5 eV still remains between the p-type GaInP and the p-type GaAs contact layer, leading to an increase in the operating voltage.

In contrast to this, there is a first example conventional semiconductor light emitting device (see, for example, Japanese Patent Publication No. 2008-78255) in which, as shown in FIG. 30, a GaInP intermediate layer 711 is provided at an interface between a p-AlGaInP cladding layer 710 and a p-GaAs cap layer 713, and a GaAs/GaInP quantum well heterobarrier intermediate layer 712 is further provided at the interface between the GaInP intermediate layer 711 and the GaAs cap layer 712, thereby reducing the operating voltage.

The first conventional semiconductor light emitting device of FIG. 30 includes an n-GaAs (15° off) substrate 701, an n-Ga_{0.508}In_{0.492}P intermediate layer (0.25 μm) 702, an n-(Al_{0.684}Ga_{0.316})_{0.511}In_{0.489}P first N cladding layer (2.6 μm) 703, an n-(Al_{0.7}Ga_{0.3})_{0.511}In_{0.489}P second N cladding layer (0.2 μm) 704, (Al_{0.545}Ga_{0.455})_{0.511}In₄₈₉P guide layers (35 nm) 705, Ga_{0.445}In_{0.555}P well layers (5 nm) 706, (Al_{0.545}Ga_{0.455})_{0.511}In_{0.489}P barrier layers (6.3 nm) 707, a p-(Al_{0.7}Ga_{0.3})_{0.511}In_{0.489}P first P cladding layer (0.272 μm) 708, a p-Ga_{0.623}In_{0.377}P etch stop layer (13 nm) 709, a p-(Al_{0.7}Ga_{0.3})_{0.511}In_{0.489}P second P cladding layer (1.2 μm) 710, a p-Ga_{0.508}In_{0.492}P intermediate layer (35 nm) 711, a heterointerface intermediate layer 712, and a p-GaAs cap layer (0.5 μm) 713. Note that, as shown in an enlarged view of a region A in FIG. 30, the heterointerface intermediate layer 712 includes GaAs layers 716a, 716b, and 716c, and GaInP layers (10 nm) 717. The three GaAs layers 716a, 716b, and 716c have different thicknesses. Each of the three GaAs layers is sandwiched between the corresponding GaInP layers 717. Specifically, the GaAs layer 716a is 2.5 nm thick, the GaAs layer 716b is 4 nm thick, and the GaAs layer 716c is 6 nm thick. The active layer has a quadruple quantum well (4MQW) structure including four well layers.

Thus, the first conventional semiconductor light emitting device includes, in the quantum well structure made of GaAs/GaInP, the heterobarrier intermediate layer between the GaInP intermediate layer and the GaAs cap layer, where the heterobarrier intermediate layer has the GaAs quantum well structure in which the thicknesses of the GaAs layers gradually decrease toward the GaInP intermediate layer (i.e., the thickness of each GaAs layer is smaller than the thicknesses of those farther away from the GaInP intermediate layer).

In this case, as shown in FIG. 4A, as the film thickness decreases, the magnitudes of quantized energy levels formed in each GaAs quantum well layer are shifted toward higher energy levels with respect to holes, and the number of energy levels formed in the quantum well decreases. In FIG. 4A, a reference character HH indicates the energies of heavy holes at quantum levels, and a reference character LH indicates the energies of light holes at quantum levels. Reference characters HH1 and LH1 indicate the ground-state energies of heavy holes and light holes, respectively. Numerals contained in HH2, HH3, etc indicate higher energy levels. Specifically, it is assumed that the widths of the GaAs wells are 2.5 nm, 4 nm, and 6 nm. In the case where the well width is 2.5 nm, two heavy hole quantum levels and one light hole quantum level are foamed. In the case where the well width is 4 nm, three heavy hole quantum levels and two light hole quantum levels are formed. In the case where the well width is 6 nm, five heavy hole quantum levels and two light hole quantum levels are formed. Therefore, a total of 15 quantum levels are formed in the GaAs/GaInP quantum well heterobarrier intermediate layer.

In this case, FIG. 4B shows a valence band structure in thermal equilibrium in the absence of an applied bias voltage, where a p-type AlGaInP cladding layer, a p-type GaInP intermediate layer, a GaAs/GaInP quantum well heterobarrier intermediate layer, and a p-type GaAs cap layer are joined together.

When a positive bias voltage is applied to the p-type GaAs cap layer, holes supplied from the GaAs cap layer are transferred through the quantum levels formed in the GaAs/GaInP quantum well heterobarrier intermediate layer to the GaInP intermediate layer. In the GaAs/GaInP quantum well heterobarrier intermediate layer, a plurality of quantum levels are formed as shown in FIG. 4B, and the energies of holes in the GaAs cap layer are maintained. Therefore, holes also easily make a transition to relatively high quantum levels, and the energy differences between higher levels and the GaInP intermediate layer are small, and therefore, holes are easily injected into the GaInP intermediate layer.

Thus, according to the first conventional semiconductor light emitting device, by inserting the GaAs/GaInP quantum well heterobarrier intermediate layer into the p-type semiconductor component layers, the influence of the heterobarrier on holes at the interface between the GaInP intermediate layer and the GaAs cap layer is reduced. As a result, holes can be injected even by applying a low voltage, and therefore, the operating voltage of the semiconductor laser can be reduced.

### SUMMARY

For semiconductor light emitting devices employing pn heterojunction, a technique of reducing or preventing the increase of the operating voltage caused by heterospikes at the interface between the p-type cladding layer and the p-type contact layer has been proposed as in the first conventional semiconductor light emitting device. However, the increase of the operating voltage caused by heterospikes formed at the heterointerface between the n-type contact layer and the n-type cladding layer has not been specifically described.

There are still large heterospikes of about 0.4 eV at the interface between the n-type GaAs buffer layer and the n-type AlGaInP cladding layer. It is necessary to add an extra bias voltage in order to pass electrons through this portion. Therefore, the operating voltage reduction effect of conventional structures is insufficient.

In the structure having the quantum well heterobarrier intermediate layer in the first conventional semiconductor light emitting device, holes injected from the p-type GaAs contact layer pass through the GaInP barrier layer due to the tunnel effect, to reach the first GaAs well layer 716c. Moreover, the holes pass through the GaInP barrier layer to reach the second and third GaAs well layers 716b and 716a. In this case, for those existing at the highest energy level of the holes distributed in the third GaAs well layer 716a, heterospikes at the interface with the GaInP intermediate layer 711 are small, and therefore, can be surmounted even when a low voltage is applied. As a result, the operating voltage can be reduced (see FIGS. 4A and 4B).

In this case, by gradually decreasing the thicknesses of the first to third GaAs well layers 716c-716a, the third GaAs well layer 716a has the smallest number of energy levels, and the magnitudes of the maximum energy levels are gradually increased. As a result, the probability that holes having a high energy exist in the third GaAs well layer 716a is increased.

However, there are still low energy levels in the third GaAs well layer 716a. Holes also exist at these levels. Therefore, it is not possible to cause injected holes to efficiently and selectively exist at high energy levels. As a result, the increase of the operating voltage caused by heterospikes cannot be efficiently reduced or prevented.

As described above, in the first conventional semiconductor light emitting device, the reduction in the operating voltage caused by heterospikes is not sufficient.

In nitride blue-violet lasers, the GaN layer or the AlGaN layer is transparent to laser oscillation light emitted from the active layer made of an InGaN material. Therefore, scattered light in the waveguide is reflected by the electrode to be fed back to the waveguide, so that the intensity of emitted light fluctuates, and therefore, the level of noise increases. Moreover, the scattered light interferes with laser light emitted from the facet, leading to a disturbance in the far-field pattern (FFP) of the emitted laser light. When the blue-violet laser is used as a light source for an optical disk system, the increase of the noise level leads to a reduction in the quality of information which is recorded or reproduced to or from an optical disk, and the disturbance of the FFP leads to a reduction in the efficiency of use of emitted laser light in the optical system of an optical pickup system. As a result, a serious problem will arise in actual use.

To solve such a problem, a second conventional semiconductor light emitting device has been proposed (see, for example, Japanese Patent Publication No. H11-251685). As shown in FIG. 31, the second conventional semiconductor light emitting device includes an n-type InGaN light absorption layer 814 having a higher absorptance than those of an n-type cladding layer 815 and an n-type GaN contact layer 812. As a result, laser light is absorbed by the light absorption layer 814, whereby it is possible to reduce or prevent scattered light in the waveguide which is reflected by an n-side electrode 826 having a large area to be fed back to the active layer. As a result, the increase of the noise level and the disturbance of the FFP can be reduced or prevented. Note that the second conventional semiconductor light emitting device of FIG. 31 further includes a sapphire substrate 810, a GaN buffer layer 811, an n-InGaN or AlGaN optical waveguide mode control layer 813, an n-GaN or InGaN guide layer 816, an n-AlGaN thin-film barrier layer 817, an InGaN-MQW active layer 818, a p-AlGaN thin-film barrier layer 819, a p-GaN or InGaN guide layer 820, a p-AlGaN cladding layer 821, a p-InGaN light absorption layer 822, a p-GaN contact layer 823, a p-InGaN or AlGaN optical waveguide mode control layer 824, and a p-type electrode 825.

Here, FIGS. 5A and 5B show the band structures of conduction bands which are obtained when the light absorption layer 814 is provided between an n-type GaN layer (substrate) and an n-type AlGaN cladding layer and when the light absorption layer 814 is not provided.

As shown in FIG. 5B, spikes formed at the interfaces between the light absorption layer 814, and the N-type AlGaN cladding layer 815 and the N-type GaN layer 812 impede electrons, and therefore, an extra voltage needs to be added in order to inject electrons injected from the N-type GaN layer 812 into the N-type AlGaN layer 815, leading to an increase in the operating voltage. For example, when the mole fraction of In in the InGaN light absorption layer 822 is 0.2 and the mole fraction of Al in the N-type AlGaN cladding layer 815 is 0.1, ΔEᵥ disadvantageously increases 0.13 eV (where the light absorption layer 814 is not provided) to 0.67 eV.

As a result, in semiconductor lasers employing nitride materials, by providing the light absorption layer near the n-type cladding layer, the disturbance of the FFP and the noise level can be reduced, however, the operating voltage disadvantageously increases.

The increase of the operating voltage leads to an increase in an increase in the operating temperature or the operating current value of the device, and as a result, a reduction in the reliability, the temperature at which the device can operate, or the light power at which the device can operate, irrespective of whether the device is an infrared laser, a red laser, or a blue-violet laser, i.e., no matter what color the light emitted by the device is.

The present disclosure describes implementations of a semiconductor laser device having a structure which allows high power operation at a low operating voltage.

A first example semiconductor light emitting device of the present disclosure includes a first cladding layer which is a semiconductor layer of a first conductivity type formed on a semiconductor substrate of the first conductivity type, an active layer formed on the first cladding layer, a second cladding layer which is a semiconductor layer of a second conductivity type formed on the active layer, and an intermediate layer formed between the first cladding layer and the substrate and including a barrier layer of the first conductivity type and two or more well layers of the first conductivity type. A forbidden band energy of the first cladding layer and forbidden band energies of the well layers satisfy a relationship represented by E1>E2, where E1 is the forbidden band energy of the first cladding layer, and E2 is the forbidden band energy of one of the well layers. The forbidden band energy of one of the well layers closer to the first cladding layer is greater than the forbidden band energy of one of the well layers closer to the substrate.

With this structure, the magnitude of the maximum energy level of electrons formed in one of the well layers closer to the first cladding layer can be greater than that of one of the well layers closer to the semiconductor substrate. As a result, as carriers injected into the well layer closer to the semiconductor substrate are conducted toward the first cladding layer to reach the well layer closer to the first cladding layer, the potential energy of the electrons increases. Therefore, a current can flow even when a low bias voltage is applied, whereby the operating voltage can be reduced.

In the first example semiconductor light emitting device of the present disclosure, the forbidden band energies of the well layers preferably monotonically increase from the substrate toward the first cladding layer.

Thus, by gradually increasing the band gap energies of a plurality of well layers of the first quantum well heterobarrier intermediate layer toward the first cladding layer, the numbers of energy levels existing in the well layers can be gradually decreased, and the magnitudes of the maximum energy levels can be gradually increased, toward the first cladding layer.

Therefore, the probability that electrons exist at the maximum energy level in the well layer closest to the first cladding layer can be increased, and the magnitude of the minimum energy level formed in the well layer can be increased. Also, carriers flowing toward the first cladding layer can pass through each barrier layer due to the tunnel effect, and carriers existing in the well layers can exist at higher energy levels as the carriers approach the first cladding layer.

Therefore, injected carriers can efficiently and selectively exist at higher energy levels as the carriers approach the first cladding layer. Therefore, even when a low bias voltage is applied, the probability that carriers surmount the energy barrier of heterospikes increases, whereby the operating voltage can be efficiently reduced.

In the first example semiconductor light emitting device of the present disclosure, a forbidden band energy of the barrier layer and forbidden band energies of the well layers preferably satisfy a relationship represented by E1≧Ec1>Ec2≧E2, where Ec1 is the forbidden band energy of the barrier layer, and Ec2 is the forbidden band energy of another of the well layers.

In this case, an increase in the operating voltage due to heterospikes occurring between the barrier layer, and the well layers closer to the first cladding layer and the semiconductor substrate, can be reduced or prevented.

In the first example semiconductor light emitting device of the present disclosure, thicknesses of the well layers preferably monotonically decrease from the substrate toward the first cladding layer.

Thus, energy levels formed in the well layers can be gradually increased, and the numbers of the levels can be gradually decreased, toward the first cladding layer.

As a result, the number of carriers existing at the maximum energy level can be greatest in the well layer closest to the first cladding layer. Therefore, electrons can pass through heterospikes occurring at the interface between the barrier layer and the well layer closer to the semiconductor substrate even when a lower bias voltage is applied, whereby the operating voltage can be further reduced.

In the first example semiconductor light emitting device of the present disclosure, a lattice constant of the barrier layer is preferably smaller than a lattice constant of the semiconductor substrate.

In this case, tensile strain occurs in the barrier layer, so that the band gap energy of the barrier layer increases. Therefore, the magnitudes of quantum level energies formed in the well layers can be increased. As a result, electrons can pass through heterospikes occurring at the interface between the barrier layer and the well layer closer to the semiconductor substrate even when a lower bias voltage is applied, whereby the operating voltage can be further reduced.

In the first example semiconductor light emitting device of the present disclosure, a lattice constant of the barrier layer is preferably smaller than a lattice constant of one of the first and second cladding layers which is closer to the barrier layer.

In this case, tensile strain occurs in the barrier layer, so that the band gap energy of the barrier layer increases. Therefore, the magnitudes of quantum level energies formed in the well layers can be increased. As a result, electrons can pass through heterospikes occurring at the interface between the barrier layer and the well layer closer to the semiconductor substrate even when a lower bias voltage is applied, whereby the operating voltage can be further reduced.

A second example semiconductor light emitting device of the present disclosure includes a first cladding layer formed on a GaAs substrate of a first conductivity type and made of AlGaInP of the first conductivity type, an active layer formed on the first cladding layer, a second cladding layer formed on the active layer and made of AlGaInP of a second conductivity type, and an intermediate layer formed between the first cladding layer and the GaAs substrate and having a multilayer structure including an (AlₓGa₁₋ₓ)_{y}In_{1-y}P barrier layer, where 0≦x≦1 and 0≦y≦1, and two or more Al_{y}Ga_{1-y}As well layers, where 0≦y<1. The Al mole fractions y of the well layers monotonically increase from the GaAs substrate toward the first cladding layer.

Thus, by gradually increasing the band gap energies of a plurality of Al_{y}Ga_{1-y}As (0≦y≦1) well layers in the first quantum well heterobarrier intermediate layer toward the first cladding layer, the numbers of energy levels existing in the quantum well heterobarrier well layers can be gradually decreased, and the magnitudes of the maximum energy levels can be gradually increased, toward the first cladding layer.

Therefore, the probability that electrons exist at the maximum energy level in the Al_{y}Ga_{1-y}As well layer closest to the first cladding layer can be increased, and the magnitude of the minimum energy level formed in the well layer can be increased. Also, carriers flowing toward the GaAs substrate can pass through each (AlₓGa₁₋ₓ)_{y}In_{1-y}P barrier layer due to the tunnel effect, and carriers existing in the well layers can exist at higher energy levels as the carriers approach the GaAs substrate.

Therefore, injected carriers can efficiently and selectively exist at higher energy levels as the carriers approach the GaAs substrate. Therefore, even when a low bias voltage is applied, the probability that carriers surmount the energy barrier of heterospikes increases, whereby the operating voltage can be efficiently reduced.

In the second example semiconductor light emitting device of the present disclosure, one of the well layers closest to the GaAs substrate preferably has an Al mole fraction between 0 and 0.1, inclusive, and one of the well layers closest to the first cladding layer preferably has an Al mole fraction between 0.2 and 0.3, inclusive.

Thus, by setting the Al mole fraction of the well layer closest to the GaAs substrate to a value between 0 and 0.1, inclusive, the number of energy levels formed in the well layer closest to the GaAs substrate can be increased, and the tunneling probability that carriers pass from the GaAs substrate through the AlGaInP barrier layer to the AlGaAs well layer closest to the AlGaInP first cladding layer can be increased.

By setting the Al mole fraction of the well layer closest to the first cladding layer to a value between 0.3 and 0.45, inclusive, the magnitudes of the energy levels in the well layers can approach the conduction band energy of the AlGaInP cladding layer, i.e., the closer the well layer is to the AlGaInP cladding layer, the closer the magnitude of the energy level in the well layer is to the conduction band energy of the AlGaInP cladding layer. Therefore, the potential energy of carriers can be efficiently increased. As a result, carriers can flow through the cladding layer even when a low bias voltage is applied, whereby the operating voltage can be reduced.

In the second example semiconductor light emitting device of the present disclosure, the well layers preferably have a thickness between 2 nm and 6 nm, inclusive, and the barrier layer preferably has a thickness between 2 nm and 8 nm, inclusive.

In this case, quantum levels can be formed in the well layers with high controllability, and the probability that carriers pass through the barrier layer due to the tunnel effect can be increased.

In the second example semiconductor light emitting device of the present disclosure, a lattice constant of the barrier layer is preferably smaller than a lattice constant of the GaAs substrate.

In this case, tensile strain occurs in the (AlₓGa₁₋ₓ)_{y}In_{1-y}P barrier layer, so that the band gap energy of the heterobarrier layer can be increased, and the magnitudes of the minimum energy levels formed in the well layers can be increased. Therefore, the potential energies of carriers existing at the minimum energy levels in the well layers can be increased. As a result, even when a bias voltage is applied, the probability that electrons surmount the energy barrier of heterospikes increases, whereby the operating voltage can be more efficiently reduced.

A third example semiconductor light emitting device of the present disclosure includes a first cladding layer formed on a GaN substrate of a first conductivity type and made of an AlGaInN material of the first conductivity type, an active layer formed on the first cladding layer, a second cladding layer formed on the active layer and made of an AlGaInN material of a second conductivity type, and a first quantum well heterobarrier intermediate layer formed between the first cladding layer and the substrate and having a multilayer structure including an Al_{xc}Ga_{yc}In_{1-xc-yc}N barrier layer, where 0≦xc<1, 0<yc≦1, and 0≦1−xc−yc<1, and two or more Al_{xc}Ga_{yc}In_{1-xc-yc}N well layers, where 0≦xw<1, 0<yw≦1, and 0≦1−xw−yw<1. Forbidden band energies of the well layers monotonically increase from the GaN substrate toward the first cladding layer.

Thus, by gradually increasing the band gap energies of a plurality of Al_{xw}Ga_{xw}In_{1-xw-yw}N well layers in the first quantum well heterobarrier intermediate layer toward the first cladding layer, the numbers of energy levels existing in the well layers can be gradually decreased, and the magnitudes of the maximum energy levels can be gradually increased, toward the GaN substrate.

Therefore, the probability that electrons exist at the maximum energy level in the Al_{xw}Ga_{yw}In_{1-xw-yw}N well layer closest to the GaN substrate can be increased, and the magnitude of the minimum energy level formed in the well layer can be increased. Also, carriers flowing toward the GaN substrate can pass through each Al_{xc}Ga_{yc}In_{1-xc-yc}N barrier layer due to the tunnel effect, and carriers existing in the well layers exist at higher energy levels as the carriers approach the GaN substrate.

Therefore, injected carriers can efficiently and selectively exist at higher energy levels as the carriers approach the GaN substrate. Therefore, even when a low bias voltage is applied, the probability that carriers surmount the energy barrier of heterospikes increases, whereby the operating voltage can be efficiently reduced.

The third example semiconductor light emitting device of the present disclosure preferably further includes a first contact layer formed between the substrate and the first quantum well heterobarrier intermediate layer. A forbidden band energy of the first contact layer is preferably smaller than a forbidden band energy of the active layer.

In this case, the first contact layer absorbs light emitted from the active layer, thereby reducing or preventing the feedback of the emitted light into the active layer after being reflected by the n-type electrode, whereby the increase of the noise level and the disturbance of the FFP can be reduced or prevented.

The third example semiconductor light emitting device of the present disclosure preferably further includes a second quantum well heterobarrier intemediate layer formed between the GaN substrate and the first contact layer and having a multilayer structure including an AlₓₛGa_{ys}In_{1-xs-ys}N near-substrate barrier layer, where 0≦xs<1, 0<ys≦1, and 0≦1−xs−ys<1, and two or more Al_{xws}Ga_{yws}In_{1-xws-yws}N near-substrate well layers, where 0≦xws<1, 0<yws≦1, and 0≦1−xws−yws<1. Forbidden band energies of the near-substrate well layers preferably monotonically increase from the first contact layer toward the GaN substrate.

Thus, by gradually decreasing the band gap energies of a plurality of Al_{xws}Ga_{yws}In_{1-xws-yws}N near-substrate well layers in the second quantum well heterobarrier intermediate layer toward the first contact layer, the numbers of energy levels existing in the near-substrate well layers can be gradually increased, and the magnitudes of the maximum energy levels can be gradually increased, toward the first contact layer.

Therefore, the probability that electrons exist at the maximum energy level in the Al_{xws}Ga_{yws}In_{1-xws-yws}N near-substrate well layer closest to the GaN substrate can be increased, and the band gap energies of the near-substrate well layers can be monotonically decreased toward the first contact layer.

When carriers flow toward the first contact layer, carriers existing in the well layers can exist at lower energy levels as the carriers approach the first contact layer having a small band gap energy.

Therefore, injected carriers are conducted through the near-substrate barrier layer due to the tunnel effect via the minimum energy state level of each well layer, to reach the first contact layer having a small band gap energy.

Therefore, even when a low bias voltage is applied, the probability that carriers surmount the energy barrier of heterospikes occurring between the second quantum well heterobarrier intermediate layer and the first contact layer increases, whereby the operating voltage can be efficiently reduced.

In the third example semiconductor light emitting device of the present disclosure, the near-substrate well layers and the well layers preferably have a thickness between 2 nm and 6 nm, inclusive, and the near-substrate barrier layer and the barrier layer preferably have a thickness between 2 nm and 8 nm, inclusive.

In this case, quantum levels can be formed in the near-substrate well layers and the well layers with high controllability, and the probability that carriers pass through the near-substrate barrier and the barrier layer due to the tunnel effect can be increased.

In the third example semiconductor light emitting device of the present disclosure, a lattice constant of the Al_{xc}Ga_{yc}In_{1-xc-yc}N barrier layer is preferably smaller than a lattice constant of the GaN substrate.

In this case, tensile strain occurs in the barrier layer, so that the band gap energy of the barrier layer can be increased. Therefore, the magnitudes of quantum level energies formed in the well layers can be increased. As a result, even when a bias voltage is applied, carriers can pass through heterospikes occurring between the first cladding layer and the first contact layer, whereby the operating voltage can be further reduced.

In the third semiconductor light emitting device of the present disclosure, a lattice constant of the AlₓₓGa_{ys}In_{1-xs-ys}N near-substrate barrier layer is preferably smaller than a lattice constant of the GaN substrate.

In this case, tensile strain occurs in the barrier layer, so that the band gap energy of the near-substrate barrier layer can be increased. Therefore, the magnitudes of quantum level energies formed in the near-substrate well layers can be increased. As a result, even when a bias voltage is applied, carriers can pass through heterospikes occurring between the substrate and the first contact layer, whereby the operating voltage can be further reduced.

According to the example structure of the present disclosure, by gradually decreasing the band gap energies of a plurality of well layers in the first quantum well heterobarrier intermediate layer toward the semiconductor substrate, the well layer closest to the semiconductor substrate has the greatest number of energy levels, and the number of energy levels in the well layer closest to the first cladding layer can be reduced while increasing the magnitudes of the energy levels.

Therefore, it is possible to increase the probability that electrons exist at the maximum energy level of the well layer closest to the first cladding layer of the first quantum well heterobarrier intermediate layer. Therefore, injected carriers can efficiently and selectively exist at a high energy level. As a result, even when a low bias voltage is applied, the probability that holes surmount the energy barrier of heterospikes occurring between the first cladding layer and the first contact layer increases, whereby the operating voltage can be efficiently reduced.

In nitride light emitting devices, when the band gap energy of the first contact layer is set to be smaller than the band gap energy of the active layer, heterospikes occur at two portions located vertically in the growth direction of the first contact layer. Also in this case, by further providing the second quantum well heterobarrier intermediate layer to gradually increase the band gap energies of a plurality of well layers toward the first contact layer, the well layer closest to the first contact layer has the greatest number of energy levels, and the magnitudes of energy levels in the well layer closest to the first cladding layer can be reduced.

Therefore, the probability that carriers injected from the substrate of the first conductivity type are conducted through the lowest one of the energy levels of quantum wells formed in heterospikes occurring between the substrate and the first contact layer, increases. Therefore, even when a low bias voltage is applied, the probability that holes surmount the energy barrier of the heterospikes increases, whereby the operating voltage can be efficiently reduced.

As described above, according to the present disclosure, the increase of the operating voltage caused by heterospikes occurring between the substrate of the first conductivity type and the first contact layer of the first conductivity type can be reduced or prevented. Therefore, even when a low bias voltage is applied, the probability that holes surmount the energy barrier of the heterospikes increases, whereby the operating voltage can be efficiently reduced.

### BRIEF DESCRIPTION OF THE DRAWINGS

FIG. 1 is a diagram showing a valence band in a p-type GaInP/p-type GaAs junction structure.

FIG. 2 is a diagram showing a conduction band in an n-type GaAs/n-type AlGaInP junction structure.

FIG. 3 is a diagram showing a conduction band in a p-type AlGaInP/p-type GaInP/p-type GaAs junction structure.

FIG. 4A is a diagram showing the relationship between the thickness of a p-type GaAs contact well layer and quantum level energies formed therein.

FIG. 4B is a diagram showing a valence band in the vicinity of an interface in a p-type GaAs contact layer/p-type GaInP intermediate layer junction in a first conventional semiconductor light emitting device.

FIG. 5A is a diagram showing a conduction band in the vicinity of an interface in an n-type GaN/n-type AlGaN junction structure.

FIG. 5B is a diagram showing a conduction band in the vicinity of an interface in an n-type GaN/n-type InGaN/n-type AlGaN junction structure.

FIG. 6A is a diagram showing a cross-sectional structure of an AlGaInP red laser device according to a first embodiment of the present disclosure.

FIG. 6B is a diagram showing a cross-sectional structure of a quantum well heterobarrier intermediate layer of the first embodiment of the present disclosure.

FIG. 7 is a diagram showing the relationship between the thickness of an n-type GaAs contact well layer of the first embodiment of the present disclosure and quantum level energies formed therein.

FIG. 8A is a diagram showing a conduction band which is obtained when an AlGaAs contact well layer (thickness: 4 nm) of the first embodiment of the present disclosure is used.

FIG. 8B is a diagram showing conduction bands which are obtained when the thickness of the AlGaAs contact well layer is 6 nm, 4 nm, and 2 nm.

FIG. 9 is a diagram showing the relationship between the Al mole fraction of the AlGaAs contact well layer (thickness: 4 nm) of the first embodiment of the present disclosure and quantum level energies formed therein.

FIG. 10 is a diagram showing conduction bands which are obtained when the Al mole fraction of the AlGaAs contact well layer (thickness: 4 nm) of the first embodiment of the present disclosure is 0.05, 0.25, and 0.45.

FIG. 11 is a diagram showing the relationship between the Al mole fraction of the AlGaAs contact well layer (thickness: 2 nm) of the first embodiment of the present disclosure and quantum level energies formed therein.

FIG. 12 is a diagram showing conduction bands which are obtained when the thickness of the AlGaAs contact well layer of the first embodiment of the present disclosure is 6 nm, 4 nm, and 2 nm, and the Al mole fraction of the AlGaAs contact well layer is 0.05, 0.25, and 0.45.

FIG. 13A is a diagram showing current-voltage characteristics of the semiconductor laser of the first embodiment of the present disclosure.

FIG. 13B is a diagram showing current-light output characteristics of the semiconductor laser of the first embodiment of the present disclosure.

FIG. 14A is a diagram showing a cross-sectional structure of a nitride blue-violet laser device according to a second embodiment of the present disclosure.

FIG. 14B is a diagram showing a cross-sectional structure of a first quantum well heterobarrier intermediate layer of the second embodiment of the present disclosure.

FIG. 15A is a diagram showing a conduction band which is obtained when the first quantum well heterobarrier intermediate layer is not provided in the second embodiment of the present disclosure.

FIG. 15B is a diagram showing a conduction band which is obtained when the first quantum well heterobarrier intermediate layer is provided in the second embodiment of the present disclosure.

FIG. 16 is a diagram showing the relationship between the Al mole fraction of an AlGaN contact well layer (thickness: 4 nm) and quantum level energies formed therein, where the Al mole fraction of an AlGaN contact barrier layer is 0.1, in the second embodiment of the present disclosure.

FIG. 17 is a diagram showing the relationship between the Al mole fraction of the AlGaN contact well layer (thickness: 4 nm) and quantum level energies formed therein, where the Al mole fraction of the AlGaN contact barrier layer is 0.2, in the second embodiment of the present disclosure.

FIG. 18 is a diagram showing the relationship between the Al mole fraction of the AlGaN contact well layer (thickness: 2 nm) and quantum level energies formed therein, where the Al mole fraction of the AlGaN contact barrier layer is 0.1, in the second embodiment of the present disclosure.

FIG. 19 is a diagram showing the relationship between the Al mole fraction of the AlGaN contact well layer (thickness: 2 nm) and quantum level energies formed therein, where the Al mole fraction of the AlGaN contact barrier layer is 0.2, in the second embodiment of the present disclosure.

FIG. 20 is a diagram showing a conduction band in an n-type GaN layer/n-type first quantum well heterobarrier intermediate layer/n-type AlGaN cladding layer junction structure.

FIG. 21A is a diagram showing a conduction band which is obtained when a multilayer structure quantum well heterobarrier intermediate layer is not provided in a third embodiment of the present disclosure.

FIG. 21B is a diagram showing a conduction band which is obtained when a multilayer structure quantum well heterobarrier intermediate layer is provided in the third embodiment of the present disclosure.

FIG. 22A is a diagram showing a cross-sectional structure of a nitride blue-violet laser device according to the third embodiment of the present disclosure.

FIG. 22B is a diagram showing a cross-sectional structure of a first quantum well heterobarrier intermediate layer of the third embodiment of the present disclosure.

FIG. 22C is a diagram showing a cross-sectional structure of a second quantum well heterobarrier intermediate layer of the third embodiment of the present disclosure.

FIG. 23 is a diagram showing the relationship between the In mole fraction of an InGaN contact well layer (thickness: 4 nm) and quantum level energies formed therein, where the Al mole fraction of an AlGaN contact barrier layer is 0.1, in the third embodiment of the present disclosure.

FIG. 24 is a diagram showing the relationship between the In mole fraction of the InGaN contact well layer (thickness: 2 nm) and quantum level energies formed therein, where the Al mole fraction of the AlGaN contact barrier layer is 0.2, in the third embodiment of the present disclosure.

FIG. 25 is a diagram showing the relationship between the In mole fraction of an InGaN contact well layer (thickness: 4 nm) and quantum level energies formed therein, where the contact barrier layer is made of GaN, in the third embodiment of the present disclosure.

FIG. 26 is a diagram showing the relationship between the In mole fraction of an InGaN contact well layer (thickness: 2 nm) and quantum level energies formed therein, where the contact barrier layer is made of GaN, in the third embodiment of the present disclosure.

FIG. 27 is a diagram showing a conduction band in an n-type GaN layer/n-type second quantum well heterobarrier intermediate layer/n-type first contact layer/n-type first quantum well heterobarrier intermediate layer/n-type AlGaN cladding layer junction structure in the third embodiment of the present disclosure.

FIG. 28 is a diagram showing a structure of a variation in which the n-type first quantum well heterobarrier intermediate layer is provided only on one of the opposite sides of the first contact layer, in the third embodiment of the present disclosure.

FIG. 29 is a diagram showing a structure of a variation in which the n-type second quantum well heterobarrier intermediate layer is provided only on one of the opposite sides of the first contact layer, in the third embodiment of the present disclosure.

FIG. 30 is a diagram showing a cross-sectional structure of the first conventional semiconductor light emitting device.

FIG. 31 is a diagram showing a cross-sectional structure of a second conventional semiconductor light emitting device.

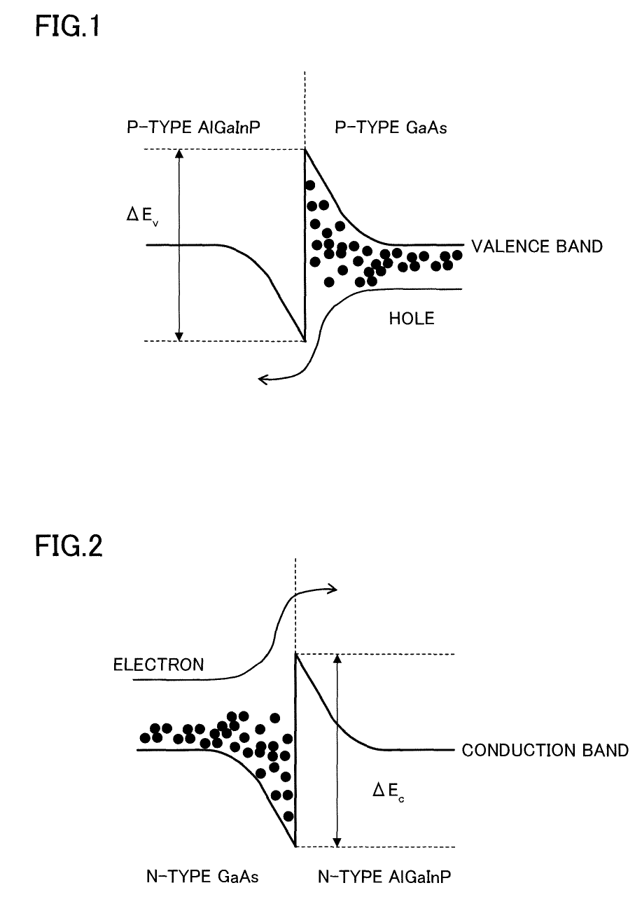

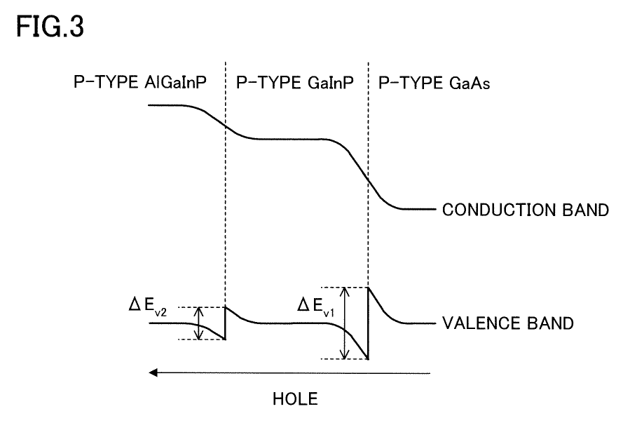

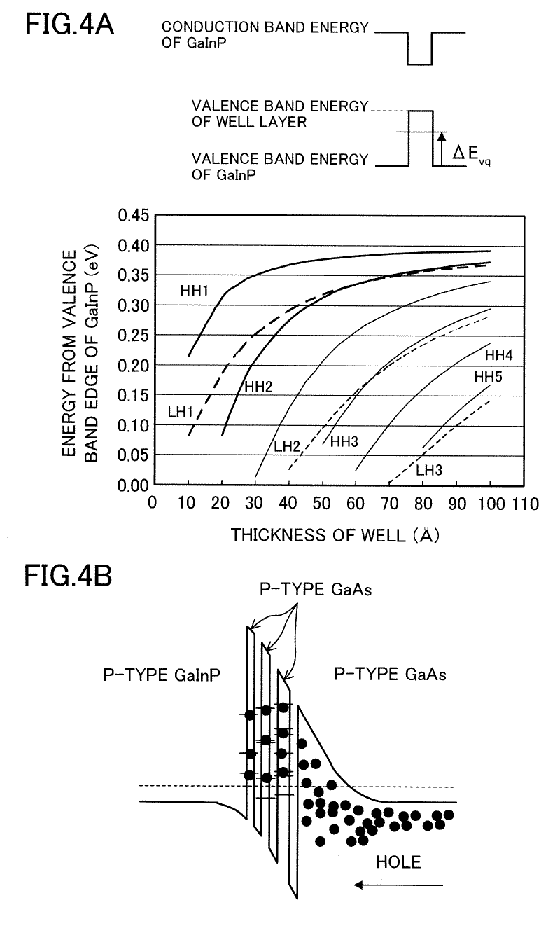

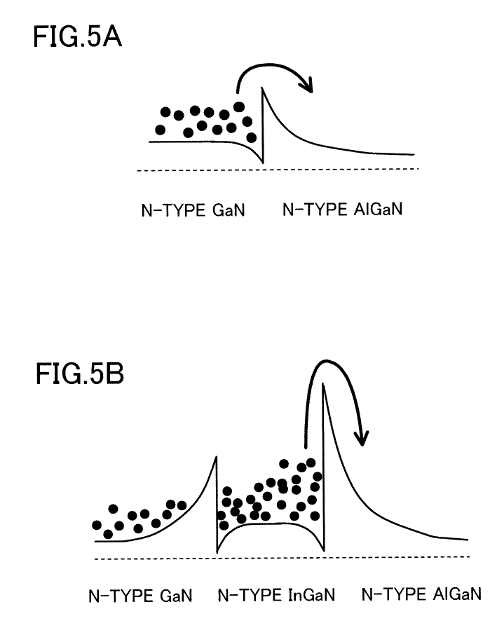

### DETAILED DESCRIPTION

Embodiments of the present disclosure will be described hereinafter with reference to the accompanying drawings. Note that the technical aspects of the present disclosure will be described in detail with reference to the drawings. Various modifications and additions can be made to the embodiments disclosed herein without departing the spirit and scope of the present disclosure by those skilled in the art after understanding the present disclosure.

### First Embodiment

A semiconductor laser device according to a first embodiment of the present disclosure includes a quantum well heterobarrier intermediate layer having a multilayer structure in which well layers are provided at an interface between a first contact layer of a first conductivity type and a first cladding layer of the first conductivity type, and the band gap energies of the well layers gradually increases toward the cladding layer of the first conductivity type (i.e., the band gap energy of each well layer is greater than the band gap energies of those farther away from the first cladding layer). As a result, the semiconductor laser device can perform high power operation at a low operating voltage.

The semiconductor laser device of the first embodiment of the present disclosure will be specifically described hereinafter with reference to the drawings.

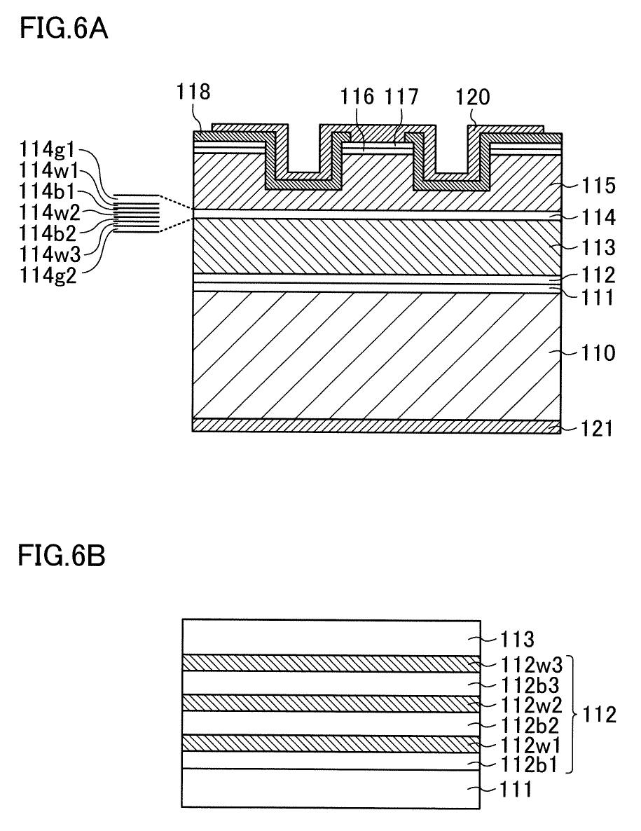

FIG. 6A is a cross-sectional view showing a structure of the semiconductor laser device of the first embodiment of the present disclosure.

As shown in FIG. 6A, on an n-type GaAs substrate 110 which has, as a main surface, a surface which is sloped at 10° relative to a (100) plane in a [011] direction, formed are an n-type GaAs contact layer 111 (0.2 μm), an n-type first quantum well heterobarrier layer 112, an n-type (Alₓ₂Ga₁₋ₓ₂)_{0.51}In_{0.49}P cladding layer 113 (2.0 μm), a strained quantum well active layer 114 including an (Al_{0.5}Ga_{0.5})_{0.51}In_{0.49}P (20 nm) first guide layer 114g1, [GaInP well layers 114w1-114w3+(Al_{0.5}Ga_{0.5})_{0.51}In_{0.49}P barrier layers 114b1 and 114b2], and an (Al_{0.5}Ga_{0.5})_{0.51}In_{0.49}P (20 nm) second guide layer 114g2, a p-type (Alₓ₁Ga₁₋ₓ₁)_{0.51}In_{0.49}P cladding layer 115, a p-type Ga_{0.51}In_{0.49}P intermediate layer 116 (50 nm), and a p-type GaAs contact layer (0.4 μm) 117.

In this case, it is assumed that the distance between an upper portion of the ridge of the p-type (Alₓ₁Ga₁₋ₓ₁)_{0.51}In_{0.49}P cladding layer 115 and the active layer 114 is 1.4 μm, and the distance between a lower end portion of the ridge and the active layer 114 is dP (0.2 μm).

Here, it is assumed that the Al mole fractions x1 and x2 of the cladding layers are 0.7, which provides the maximum band gap energy, in order to reduce or prevent overflow of carriers injected into the active layer 114 which occurs due to heat.

A dielectric current blocking layer (0.7 μm) 118 made of SiN is formed on a side surface of the ridge. In this structure, a current injected from the p-type GaAs contact layer 117 is confined only into the ridge portion by the current blocking layer 118, so that the current is injected and concentrated into the active layer 114 located below a bottom portion of the ridge. As a result, a carrier population inversion required for laser oscillation is produced by an injected current of as low as several tens of milliamperes. Light generated in this case by recombination of carriers injected into the active layer 114 is confined in a direction perpendicular to the active layer 114 by the cladding layers 113 and 115 (vertical optical confinement), and is also confined in a direction parallel the active layer 114 by the current blocking layer 118 (horizontal optical confinement) because the current blocking layer 118 has a lower refractive index than those of the cladding layers 113 and 115. Because the current blocking layer 118 is transparent to laser oscillation light, i.e., light absorption does not occur, a waveguide with low loss can be provided. A distribution of light propagating through the waveguide can significantly spread into the current blocking layer 118, and therefore, Δn of the order of 10⁻³ which is suitable for high-power operation can be easily obtained. Moreover, the magnitude of Δn is the same as that of dP, and can also be precisely controlled on the order of 10⁻³. Therefore, a high-power semiconductor laser with a low operating current can be provided in which the distribution of light can be precisely controlled.

When a semiconductor laser device is used as a light source for recording and reproduction of an optical disk system, the distribution of light of the semiconductor laser needs to be one that is produced by oscillation operation in a single-peak fundamental transverse mode, in order to condense emitted laser light onto an optical disk.

In order to generate fundamental transverse mode oscillation even in a high-temperature and high-power state, the structure of the waveguide needs to be decided so that higher-order transverse modes are cut off to avoid laser oscillation. To do this, not only Δn needs to be precisely controlled on the order of 10⁻³, but also the width of the bottom portion of the ridge needs to be narrowed, to cut off higher-order transverse modes.

The width of the bottom portion of the ridge needs to be narrowed to 3 μm or less in order to reduce or prevent higher-order transverse mode oscillation. If the width of the bottom portion of the ridge is narrowed, the width of the upper surface of the ridge is also narrowed according to the mesa shape of the ridge. If the width of the upper surface of the ridge is excessively narrowed, the width of a path of a current injected from above the ridge toward the device is narrowed, so that the serial resistance (Rs) of the device increases, and therefore, the operating voltage increases. Therefore, if the width of the bottom portion of the ridge is simply narrowed in order to generate stable fundamental transverse mode oscillation, Rs increases, and therefore, the operating voltage increases. This leads to heat generation, which makes it difficult to achieve high-temperature and high-power operation.

Therefore, in the first embodiment of the present disclosure, the n-type quantum well heterobarrier layer 112 is provided between the n-type GaAs first contact layer 111 (0.2 μm) and the n-type AlGaInP cladding layer 113 (2.0 μm). As shown in FIG. 6B, the n-type quantum well heterobarrier layer 112 includes three n-type contact well layers 112w1-112w3 and three n-type contact barrier layers 112b1-112b3. The contact well layers 112w1-112w3 are each made of n-type Al_{y}Ga_{1-y}As, and the contact barrier layers 112b1-112b3 are each made of n-type (AlₓGa₁₋ₓ)_{y}In_{1-y}P.

Here, electrical conduction of electrons in the quantum well heterobarrier layer 112 will be discussed.

When a bias voltage is applied to the device, so that a current starts flowing through the semiconductor laser, electrons injected from the first contact layer 111 firstly pass through the contact barrier layer 112b1 and then through the contact well layer 112w1. In this case, if the thickness of the contact barrier layer 112b1 is decreased so that electrons can pass through the contact barrier layer 112b1 due to the tunnel effect, the electrons can reach the contact well layer 112w1 even at a low bias voltage irrespective of a heterobarrier at the interface between the contact barrier layer 112b1 and the first contact layer 111. In order to exhibit the tunnel effect, the thicknesses of the contact barrier layers 112b1-112b3 need to be smaller than or equal to approximately the wavelength of an electron wave function, i.e., needs to be 8 nm or less. Note that if the thicknesses of the contact barrier layers 112b1-112b3 are excessively decreased, the quantum levels of the contact well layers 112w1-112w3 are strongly coupled to form minibands, so that the quantum level of electrons formed in each of the contact well layers 112w1-112w3 is split, and therefore, the probability that electrons exist at a low energy state in the contact well layers 112w1-112w3 increases. Therefore, when electrons are conducted from the contact well layer 112w3 to the n-type AlGaInP cladding layer 113, the proportion of electrons which are significantly affected by the heterobarrier still increases, and therefore, the operating voltage reduction effect is reduced. Therefore, in order to obtain a high tunneling probability and reduce or prevent the formation of minibands caused by the coupling of the quantum levels of electrons between the contact well layers 112w1-112w3, the thicknesses of the contact barrier layers 112b1-112b3 need to be set to a value between 2 nm and 8 nm, inclusive. In the first embodiment of the present disclosure, for example, the thicknesses of the contact barrier layers 112b1-112b3 are 6 nm.

Next, an influence of the band gap energy of a contact well layer on electrical conduction of electrons will be discussed.

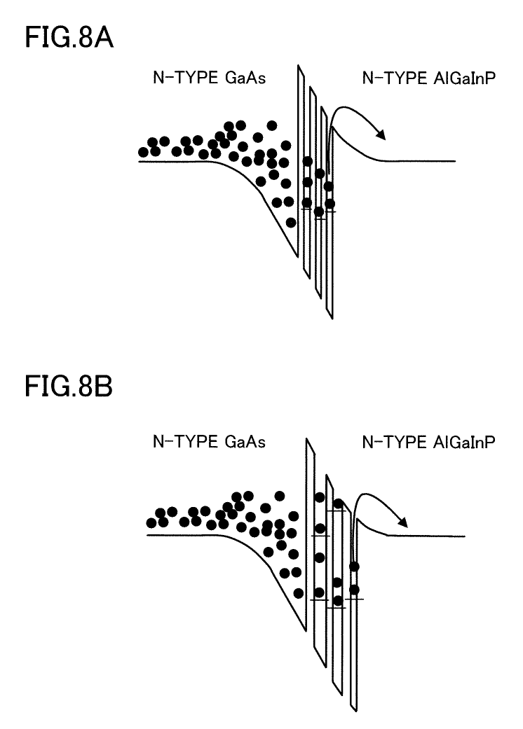

FIG. 8A shows a conduction band diagram which is obtained when an AlGaAs contact well layer (thickness: 4 nm) is used. FIG. 8B shows a conduction band diagram which is obtained when the thickness of the AlGaAs contact well layer is 6 nm, 4 nm, and 2 nm.

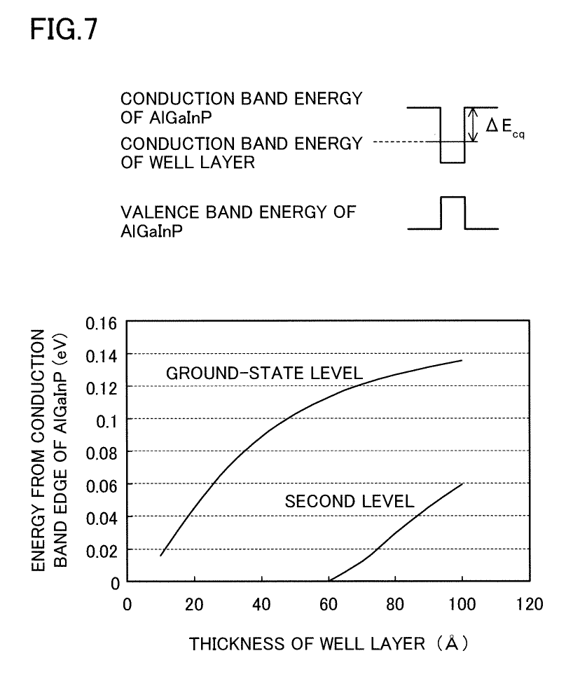

As can be seen from the result of calculation of energy with respect to the thickness of the contact well layer shown in FIG. 7, when the contact well layers of a quantum well heterobarrier layer are all made of the same material (e.g., GaAs), then even if the thickness of each contact well layer is decreased to 2 nm or less, a quantum level for electrons formed in the conduction band is higher by as small as about 0.1 eV than the conduction band edge energy of the contact well layer. Therefore, as shown in FIG. 8A, an energy barrier (ΔE_{cq}) exists which is about 0.04 eV as measured from the conduction band edge of the n-type AlGaInP cladding layer.

Therefore, as shown in FIG. 8B, even if the thicknesses of the three GaAs contact well layers 112w1-112w3 are gradually decreased from 6 nm to 2 nm toward the n-type AlGaInP cladding layer 113, the lowest energy magnitude of the quantum level for electrons increases by as small as about 0.08 eV or less. Therefore, in the contact well layer 112w3 contacting the n-type AlGaInP cladding layer 113, even if the quantum level of electrons having a heterobarrier with a reduced magnitude is formed so that the energy level of electrons having the maximum energy, and the magnitude of energy as measured from the conduction band edge of the n-type AlGaInP cladding layer 113, are 0.04 eV, electrons still exist at the ground-state quantum level. As a result, the magnitude of the heterobarrier cannot be efficiently reduced for all electrons existing between the GaAs contact layer and the n-type AlGaInP cladding layer.

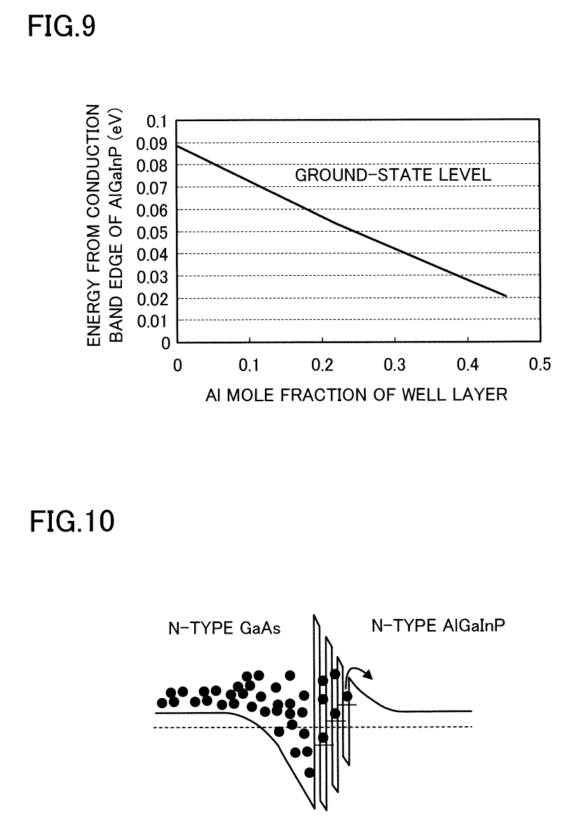

Therefore, in the semiconductor laser device of the first embodiment of the present disclosure, the contact well layers 112w1-112w3 are made of AlGaAs, and the Al mole fractions of the contact well layers 112w1-112w3 are gradually changed so that the band gap energies of the contact well layers 112w1-112w3 gradually increase toward the n-type cladding layer 113. Here, FIG. 9 shows the magnitudes of the energy levels of electrons formed in the contact well layers 112w1-112w3 which are obtained when the Al mole fractions of the contact well layers 112w1-112w3 are changed from 0 to 0.45, where the thicknesses of the contact well layers 112w1-112w3 are 4 nm, which can provide a quantum effect, and the contact barrier layers 112b1-112b3 are made of AlGaInP. As in FIG. 7, FIG. 9 shows the magnitudes of energies as measured from the conduction band edge energy of the n-type AlGaInP cladding layer 113.

As shown in FIG. 9, as the Al mole fractions of the contact well layers 112w1-112w3 increase, the ground-state quantum level of electrons formed in the contact well layers 112w1-112w3 approaches the conduction band edge energy of the n-type AlGaInP cladding layer 113. When the Al mole fraction is 0.45, the difference between the conduction band edge energy of the n-type AlGaInP cladding layer 113 and an energy formed in the contact well layers 112w1-112w3 is reduced to 0.02 eV. When the Al mole fraction of the contact well layers 112w1-112w3 is 0.45 or more, the band structure of the AlGaAs material is of an indirect bandgap, and therefore, the magnitude of the energy of the conduction band of AlGaAs is reduced. Therefore, when the Al mole fraction is 0.45 or more, ΔE_{cq} conversely increases with an increase in the Al mole fraction. Therefore, when the contact well layers 112w1-112w3 are made of AlGaAs, the Al mole fraction needs to fall within the range of 0.45 or less.

If the Al mole fraction of the contact well layer 112w1 closest to the n-type GaAs contact layer 111 is set to be low, and the Al mole fractions of the contact well layers 112w2 and 112w3 are gradually increased toward the n-type AlGaInP cladding layer 113, the energy of electrons existing in the contact well layers 112w2 and 112w3 can efficiently approach the conduction band edge energy of the n-type AlGaInP cladding layer 113 as the electrons are conducted through the contact well layers 112w2 and 112w3.

In particular, if the Al mole fraction of the contact well layer 112b1 closest to the GaAs contact layer 111 is set to a value between 0 and 0.1, inclusive, as shown in FIG. 9 the energy level of ground-state electrons formed in the contact well layers 112w1-112w3 is moved closer to the conduction band edge of the GaAs contact layer 111 by about 0.1 eV. Therefore, electrons injected from the GaAs contact layer 111 can be injected into the contact well layer 112b1 due to the tunnel effect without encountering a great heterobarrier.

If the Al mole fraction of the contact well layer 112b3 closest to the n-type cladding layer 113 is set to a value between 0.3 and 0.45, inclusive, the magnitude of a heterobarrier which is encountered by electrons existing in the contact well layer 112b3 as the electrons are conducted through the n-type AlGaInP cladding layer 113 can be set to 0.04 eV or less as shown in FIG. 9. Therefore, the electrons existing in the contact well layer 112b3 can be injected into the n-type AlGaInP cladding layer 113 without encountering a great heterobarrier.

Specifically, in the semiconductor laser device of the first embodiment of the present disclosure, the contact well layer includes the three contact well layers 112w1-112w3, and the Al mole fractions of the three contact well layers 112w1-112w3 are set to 0.05, 0.25, and 0.45, which gradually increase toward the n-type AlGaInP cladding layer 113.

Here, moreover, as described above, if the thicknesses of the contact barrier layers 112b1-112b3 are set to a value between 2 nm and 8 nm, inclusive, which can provide the tunnel effect (e.g., 4 nm in the first embodiment), an increased proportion of electrons pass from the contact layer 111 through the quantum well heterobarrier layer 112b1 due to the tunnel effect. As shown in FIG. 10, as electrons are conducted from the contact well layer 112b1 to the contact well layer 112b3, i.e., through the quantum well heterobarrier layer 112, due to the tunnel effect, efficient electrical conduction can be achieved via a high energy level of electrons. In this case, the magnitude of energy as measured from the conduction band edge energy of the n-type AlGaInP cladding layer 113 is reduced to 0.02 eV with respect to the maximum energy level of electrons formed in the contact well layer 112b3, and therefore, even when a low bias voltage is applied, electrons can be conducted from the GaAs contact layer 111 to the n-type AlGaInP cladding layer 113.

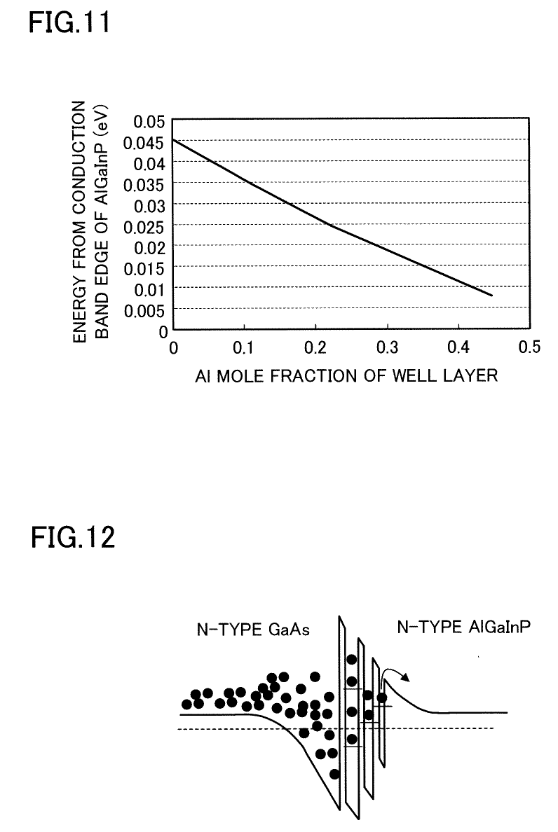

FIG. 11 shows the magnitudes of energy levels which are obtained when the Al mole fractions of the quantum well contact well layers 112w1-112w3 made of AlGaAs are varied, where the thicknesses of the contact well layers 112w1-112w3 are 2 nm. As in FIG. 7, FIG. 11 also shows the magnitude (ΔE_{cq}) of the difference between an energy at the conduction band edge of the n-type AlGaInP cladding layer 113 and a quantum level energy.

As shown in FIG. 11, as the thicknesses of the contact well layers 112w1-112w3 decrease, the energy levels of electrons formed in the contact well layers 112w1-112w3 increase, and therefore, ΔE_{cq} is greater than that is obtained when the thicknesses of the contact well layers 112w1-112w3 are 4 nm. Therefore, the probability that electrons pass through the contact barrier layer 112b1 due to the tunnel effect decreases. When interface layers form mixed crystal at the interfaces between the contact well layers 112w1-112w3 and the contact barrier layers 112b1-112b3, the average Al mole fractions of the contact well layers 112w1-112w3 further increase, so that the number of quantum levels decreases, and therefore, the tunneling probability of electrons is likely to decrease.

On the other hand, as shown in FIG. 11, as the thicknesses of the contact well layers 112w1-112w3 increase, the numbers of levels of electrons formed in the contact well layers 112w1-112w3 increase, and therefore, the probability that electrons efficiently exist in a high energy state, i.e., at an energy level closest to the conduction band edge energy of the n-type GaAs contact layer 111, decreases. Therefore, the thicknesses of the contact well layers 112w1-112w3 need to be set to a value between 2 nm and 6 nm, inclusive. In the first embodiment of the present disclosure, as an example, the thicknesses of the contact well layers 112w1-112w3 are 4 nm.

Alternatively, as shown in FIG. 12, the Al mole fractions and the thicknesses of the contact well layers 112w1-112w3 may be gradually increased toward the n-type AlGaInP cladding layer 113. Specifically, the thickness and the Al mole fraction of the AlGaAs contact well layer 112w1 closest to the GaAs contact layer 111 may be 6 nm and 0.05, respectively, the thickness and the Al mole fraction of the AlGaAs contact well layer 112w2 may be 4 nm and 0.25, respectively, and the thickness and the Al mole fraction of the AlGaAs contact well layer 112w3 may be 2 nm and 0.45, respectively. In this case, the energies of electrons existing in the AlGaAs contact well layers 112w1-112w3 can gradually approach the conduction band edge energy of the n-type AlGaInP cladding layer 113, i.e., the closer the contact well layer is to the n-type AlGaInP cladding layer 113, the closer the energy of electrons existing in the contact layer is to the conduction band edge energy of the n-type AlGaInP cladding layer 113. As a result, electrons injected from the GaAs contact layer 111 can efficiently exist at a quantum level energy closest to the conduction band edge energy of the n-type AlGaInP cladding layer 113 in the contact well layer 112w3, whereby the operating voltage can be further reduced.

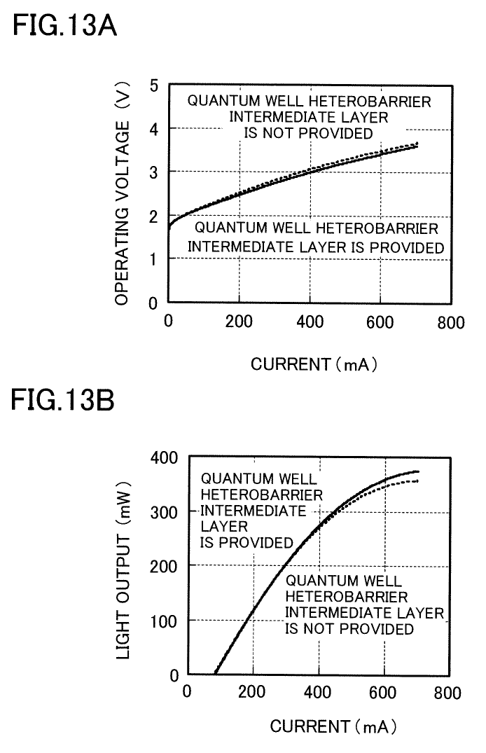

FIG. 13A shows current-voltage characteristics of the semiconductor laser device of the first embodiment of the present disclosure. In the semiconductor laser device of this embodiment, the operating voltage can be reduced by about 0.1 V by using the quantum well heterobarrier layer 112. FIG. 13B shows current-light output characteristics of the semiconductor laser device of the first embodiment of the present disclosure. Specifically, the current-light output characteristics are measured during high-temperature pulse drive at 85° C., 50 ns, and a duty cycle of 50%. As can be seen from FIG. 13B, by using the quantum well heterobarrier layer 112, the level of thermal saturation is improved by about 20 mW.

As described above, the semiconductor laser device of this embodiment includes the quantum well heterobarrier layer 112 between the n-type GaAs contact layer 111 and the n-type AlGaInP cladding layer 113, thereby reducing or preventing the increase of the operating voltage caused by heterospikes.

While the example in which the semiconductor laser device of this embodiment is a red laser which includes, as the active layer, the quantum well active layer 114 made of AlGaInP materials including GaInP, has been described above, the semiconductor laser device of this embodiment may be an infrared laser including an active layer made of AlGaAs materials including GaAs. In this case, similarly, by providing the quantum well heterobarrier layer 112 between the n-type GaAs contact layer 111 and the n-type AlGaInP cladding layer 113, the increase of the operating voltage caused by heterospikes can be reduced or prevented.

### Second Embodiment

A semiconductor laser device according to a second embodiment of the present disclosure includes a quantum well heterobarrier intermediate layer provided at an interface between a substrate of a first conductivity type and a first cladding layer of the first conductivity type. The quantum well heterobarrier intermediate layer has a multilayer structure including well layers whose band gap energies gradually increase toward the first cladding layer of the first conductivity type (i.e., the band gap energy of each well layer is greater than the band gap energies of those farther away from the first cladding layer). As a result, even when the semiconductor laser device is made of nitride materials, the semiconductor laser device can perform high-power operation at a low operating voltage.

The semiconductor laser device of the second embodiment of the present disclosure will be specifically described hereinafter with reference to the drawings.

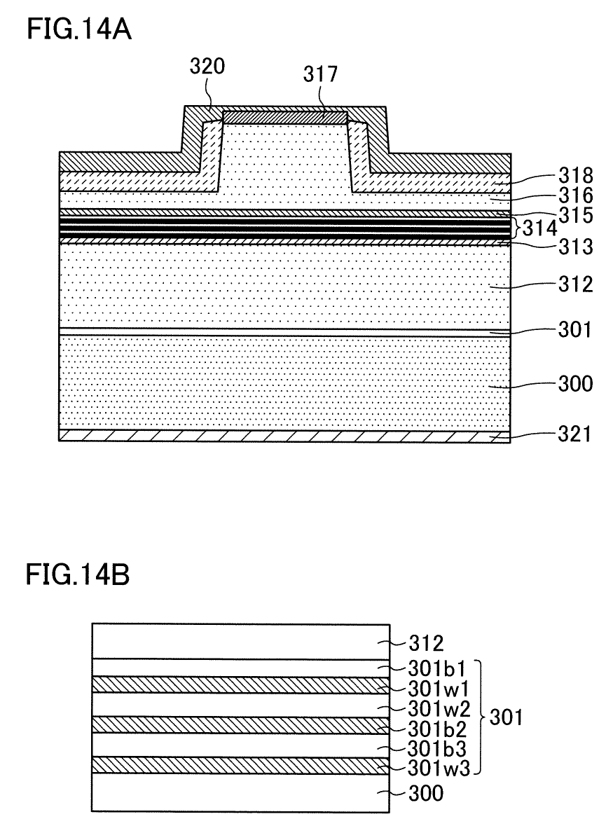

FIG. 14A is a diagram showing a cross-sectional structure of the semiconductor laser device of the second embodiment of the present disclosure.

As shown in FIG. 14A, on a GaN substrate 300, formed are an n-type first quantum well heterobarrier layer 301, an n-type AlGaN cladding layer (thickness: 2.5 μm) 312, an n-type AlGaN guide layer (86 nm) 313, a InGaN quantum well active layer 314, a p-type AlGaN electron blocking layer (thickness: 10 nm) 315, a p-type AlGaN cladding layer 316, a p-type GaN contact layer (thickness: 0.1 μm) 317, a first current blocking layer 318 transparent to a distribution of light, a p-type electrode 320, and an n-type electrode 321. The ridge has a width (W) of 1.4 μm.

In this case, it is assumed that the distance between an upper portion of the ridge of the p-type AlGaN cladding layer 316 and the active layer 314 is 0.5 μm, and the distance between a lower end portion of the ridge and the active layer 314 is dP (0.1 μm).

Here, in the semiconductor laser device of the second embodiment of the present disclosure, in order to reduce or prevent overflow into the cladding layer of carriers which are injected into the active layer and are then excited by heat during operation, the Al mole fractions of the n-type AlGaN cladding layer 312 and the p-type AlGaN cladding layer 315 are set to 0.1. By increasing the Al mole fractions of the n-type AlGaN cladding layer 312 and the p-type AlGaN cladding layer 316, the difference in band gap energy between the active layer and the cladding layer can be increased, whereby the overflow of carriers injected into the active layer can be reduced or prevented. However, because of the difference in thermal expansion coefficient between the AlGaN layer and the GaN substrate, a lattice defect occurs if the Al mole fraction of the AlGaN cladding layer is excessively increased, leading to a degradation in reliability. Therefore, the Al mole fraction of the AlGaN cladding layer needs to be 0.2 or less.

A dielectric current blocking layer (0.1 μm) 318 made of SiN is formed on a side surface of the ridge. In this structure, a current injected from the p-type GaN contact layer 317 is confined only into the ridge portion by the current blocking layer 318, so that the current is injected and concentrated into the active layer 314 located below a bottom portion of the ridge. As a result, a carrier population inversion required for laser oscillation is produced by an injected current of as low as several tens of milliamperes. Light generated in this case by recombination of carriers injected into the active layer 314 is confined in a direction perpendicular to the active layer 314 by the cladding layers 312 and 316 (vertical optical confinement), and is also confined in a direction parallel the active layer 314 by the current blocking layer 318 (horizontal optical confinement) because the current blocking layer 318 has a lower refractive index than those of the cladding layers 312 and 316. Because the current blocking layer 318 is transparent to laser oscillation light, i.e., light absorption does not occur, a waveguide with low loss can be provided. A distribution of light propagating through the waveguide can significantly spread into the current blocking layer 318, and therefore, Δn of the order of 10⁻³ which is suitable for high-power operation can be easily obtained. Moreover, the magnitude of Δn is the same as that of dP, and can also be precisely controlled on the order of 10⁻³. Therefore, a high-power semiconductor laser with a low operating current can be provided in which the distribution of light can be precisely controlled.

When a semiconductor laser device is used as a light source for recording and reproduction of an optical disk system, the distribution of light of the semiconductor laser needs to be one that is produced by oscillation operation in a single-peak fundamental transverse mode, in order to condense emitted laser light onto an optical disk to the diffraction limit.

In order to generate fundamental transverse mode oscillation even in a high-temperature and high-power state, the structure of the waveguide needs to be decided so that higher-order transverse modes are cut off to avoid laser oscillation. To do this, not only Δn needs to be precisely controlled on the order of 10⁻³, but also the width of the bottom portion of the ridge needs to be narrowed to cut off higher-order transverse modes.

The width of the bottom portion of the ridge needs to be narrowed to 1.5 μm or less in order to reduce or prevent higher-order transverse mode oscillation. If the width of the bottom portion of the ridge is narrowed, the width of the upper surface of the ridge is also narrowed according to the mesa shape of the ridge. If the width of the upper surface of the ridge is excessively narrowed, the width of a path of a current injected from above the ridge toward the device is narrowed, so that the serial resistance (Rs) of the device increases, and therefore, the operating voltage increases. Therefore, if the width of the bottom portion of the ridge is simply narrowed in order to generate stable fundamental transverse mode oscillation, Rs increases, and therefore, the operating voltage increases. This leads to heat generation, which makes it difficult to achieve high-temperature and high-power operation.

Therefore, in the second embodiment of the present disclosure, the n-type first quantum well heterobarrier layer 301 is provided between the n-type GaN substrate 300 and the n-type AlGaN cladding layer 312. As shown in FIG. 14B, the n-type first quantum well heterobarrier layer 301 includes three n-type contact well layers 301w1-301w3 and three contact barrier layers 301b1-301b3. The contact barrier layers 301b1-301b3 are made of n-type AlGaN as with the n-type AlGaN cladding layer 312.

Here, a structure of the quantum well heterobarrier layer will be described.

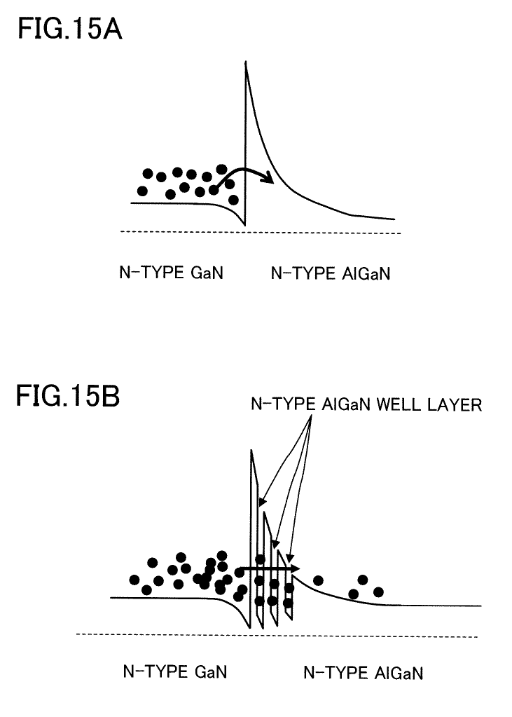

In a structure which does not include the first quantum well heterobarrier intermediate layer 301, when the Al mole fraction of the n-type AlGaN cladding layer 312 is set to 0.1 and 0.2, as shown in FIG. 15A heterobarriers of 0.127 eV and 0.167 eV, respectively, for electrons are formed at the interface with the n-type GaN substrate 300. The heterobarrier causes not only an increase in a rising voltage in the current-voltage characteristics, but also an increase in the serial resistance (Rs), leading to an increase in the operating voltage. Nitride semiconductor lasers inherently have a high operating voltage because nitride materials inherently have a great band gap energy, and therefore, it is considerably important to reduce the operating voltage.

Therefore, in the second embodiment of the present disclosure, the quantum well heterobarrier intermediate layer 301 including the three contact well layers 301w1-301w3 is provided between the n-type AlGaN cladding layer 312 and the n-type GaN substrate 300 (see FIG. 15B).

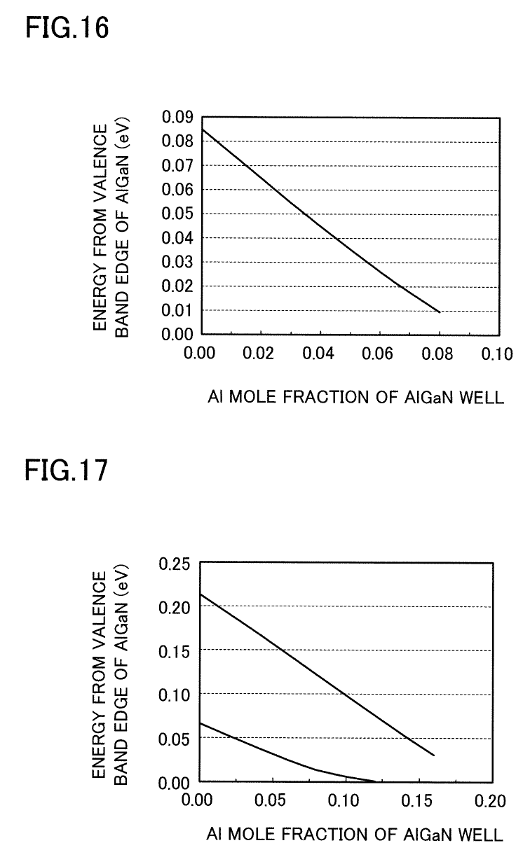

Here, FIG. 16 shows the result of calculation of the energy levels of electrons formed in the contact well layers 301w1-301w3, which are obtained when the Al mole fractions of the contact well layers 301w1-301w3 are changed from 0 to 0.08, where the Al mole fraction of the n-type AlGaN cladding layer 312 is 0.1, the contact barrier layers 301b1-301b3 are made of AlGaN having an Al mole fraction of 0.1, and the contact well layers 301w1-301w3 are an AlGaN layer having a thickness of 4 nm. Note that the calculation result shows differences in quantum level energy as measured from the conduction band edges of the AlGaN contact barrier layers 301b1-301b3.

As can be seen from the calculation result of FIG. 16, if the Al mole fractions of the contact well layers 301w1-301w3 are set to 0.02, 0.05, and 0.08, which gradually increase toward the n-type AlGaN cladding layer 312, the energy levels of ground-state electrons formed in the contact well layers 301w1-301w3 can be set to 0.063 eV, 0.038 eV, and 0.01 eV, which gradually approach the conduction band edge of the n-type AlGaN cladding layer 312 (these values are spaced a small interval (about 0.02 eV) apart), where these values are measured from the conduction band edge of the n-type AlGaN cladding layer 312. Therefore, the energy level of electrons injected from the n-type GaN substrate 300 toward the n-type AlGaN cladding layer 312 efficiently increases as the electrons approach the n-type AlGaN cladding layer 312 before reaching the n-type AlGaN cladding layer 312 via the first quantum well heterobarrier layer 301. As a result, the increase of the operating voltage can be reduced or prevented.

FIG. 17 shows the result of calculation of the energy levels of electrons formed in the contact well layers 301w1-301w3, which are obtained when the Al mole fractions of the contact well layers 301w1-301w3 are changed from 0 to 0.16, where the Al mole fraction of the n-type AlGaN cladding layer 312 is 0.2, the contact barrier layers 301b1-301b3 are made of AlGaN having an Al mole fraction of 0.2, and the contact well layers 301w1-301w3 are an AlGaN layer having a thickness of 4 nm. Note that the calculation result shows differences in quantum level energy as measured from the conduction band edges of the AlGaN contact barrier layers 301b1-301b3.

As can be seen from the calculation result of FIG. 17, if the Al mole fractions of the contact well layers 301w1-301w3 are set to 0.025, 0.08, and 0.16, which gradually increase toward the n-type AlGaN cladding layer 312, the energy levels of ground-state electrons formed in the contact well layers 301w1-301w3 can be set to 0.18 eV, 0.115 eV, and 0.03 eV, which gradually approach the conduction band edge of the n-type AlGaN cladding layer 312 (these values are spaced a small interval (about 0.07 eV) apart), where these values are measured from the conduction band edge of the n-type AlGaN cladding layer 312. Therefore, the energy level of electrons injected from the n-type GaN substrate 300 toward the n-type AlGaN cladding layer 312 efficiently increases as the electrons approach the n-type AlGaN cladding layer 312 before reaching the n-type AlGaN cladding layer 312 via the first quantum well heterobarrier layer 301. As a result, the increase of the operating voltage can be reduced or prevented.

If the Al mole fraction of the contact well layer 301w3 closest to the n-type GaN substrate 300 is set to a value between 0 and 0.05, inclusive, the energy level of ground-state electrons formed in the contact well layer 301w3 can be moved closer to the energy of electrons in the conduction band of n-type GaN, and therefore, the probability that electrons pass through the contact barrier layer 301b3 due to the tunnel effect increases, whereby the operating voltage can be reduced.

By setting the Al mole fractions of the contact well layers 301w1-301w3 to be smaller than or equal to the Al mole fraction of the n-type AlGaN cladding layer 312, the energies of holes formed in the contact well layers 301w1-301w3 can be prevented from being higher than necessary.

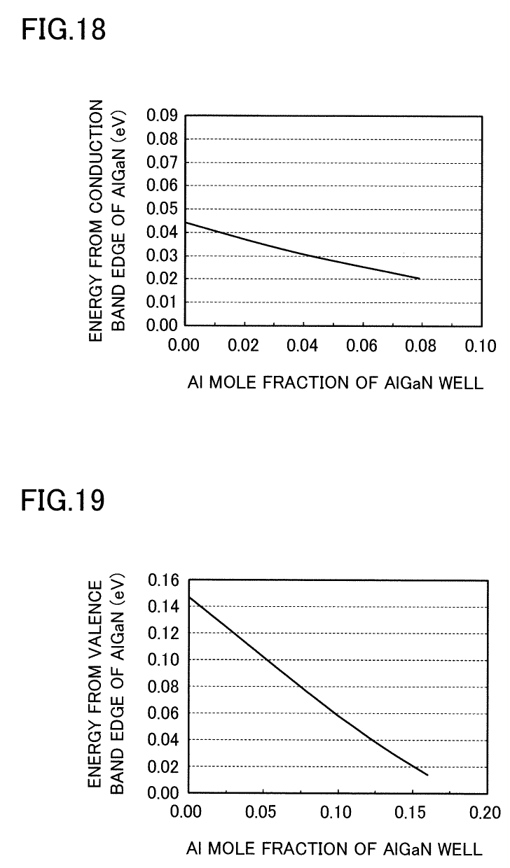

FIGS. 18 and 19 show the result of calculation of the dependency of the quantum level energies of electrons formed in the contact well layers 301w1-301w3 on the Al mole fractions of the AlGaN contact well layers 301w1-301w3, where the thicknesses of the contact well layers 301w1-301w3 are 2 nm, and the Al mole fractions of the AlGaN the contact barrier layers 301b1-301b3 are 0.1 or 0.2. Note that the calculation result shows differences in quantum level energy as measured from the conduction band edges of the AlGaN contact barrier layers 301b1-301b3.

As can be seen from the calculation result of FIGS. 16-19, as the thicknesses of the contact well layers 301w1-301w3 are decreased, the quantum level energies of the contact well layers 301w1-301w3 approach the energies of the conduction bands of the contact barrier layers 301b1-301b3, where the Al mole fractions of the contact well layers 301w1-301w3 are the same. When the Al mole fractions of the contact well layers 301w1-301w3 are 0.05, and the Al mole fractions of the contact barrier layers 301b1-301b3 are 0.2, then if the thicknesses of the contact well layers 301w1-301w3 are decreased from 4 nm to 2 nm, the energy differences between the conduction bands of the contact barrier layers 301b1-301b3 and the ground-state quantum levels of the contact well layers 301w1-301w3 decrease from 0.16 eV to 0.1 eV. This means that as the thicknesses of the contact well layers 301w1-301w3 are decreased, the energies at the ground-state quantum level of the contact well layers 301w1-301w3 as measured from the conduction band energy of n-type GaN are likely to increase. Therefore, if the thicknesses of the contact well layers 301w1-301w3 are excessively decreased, the probability that electrons from the n-type GaN substrate pass through the contact barrier layers 301b1-301b3 due to the tunnel effect to reach the contact well layers 301w3-301w1 decreases.

When interface layers form mixed crystal at the interfaces between the contact well layers 301w1-301w3 and the contact barrier layers 301b1-301b3, the average Al mole fractions of the contact well layers 301w1-301w3 further increase, so that the ground-state quantum levels of the contact well layers 301w1-301w3 further increase, and therefore, the tunneling probability of electrons is likely to further decrease.

Conversely, if the thicknesses of the contact well layers 301w1-301w3 are increased, the quantum level energies of electrons formed in the contact well layers 301w1-301w3 decrease, and therefore, the differences from the conduction band energies of the contact barrier layers 301b1-301b3 increase. Therefore, the probability that electrons efficiently exist at a high energy state, i.e., an energy level closest to the conduction band edge energy of AlGaN, decreases. Therefore, the thicknesses of the contact well layers 301w1-301w3 need to be set to a value between 2 nm and 6 nm, inclusive. In the second embodiment of the present disclosure, the thicknesses of the contact well layers 301w1-301w3 are 4 nm.

In order to exhibit the tunnel effect in the contact barrier layers 301b1-301b3, the thicknesses of the contact barrier layers 301b1-301b3 need to be smaller than or equal to approximately the wavelength of an electron wave function, i.e., needs to be 8 nm or less. Note that if the thicknesses of the contact barrier layers 301b1-301b3 are excessively decreased, the quantum levels of the contact well layers 301w1-301w3 are strongly coupled to form minibands, so that the quantum level of electrons formed in each of the contact well layers 301w1-301w3 is split, and therefore, the probability that electrons exist at a low energy state in the contact well layers 301w1-301w3 increases. Therefore, when electrons are conducted from the contact well layer 301w3 to the n-type AlGaInP cladding layer 312, the proportion of electrons which are significantly affected by the heterobarrier still increases, and therefore, the operating voltage reduction effect is reduced. Therefore, in order to obtain a high tunneling probability and reduce or prevent the formation of minibands caused by the coupling of the quantum levels of electrons between the contact well layers 301w1-301w3, the thicknesses of the contact barrier layers 301b1-301b3 need to be set to a value between 2 nm and 8 nm, inclusive. In the second embodiment of the present disclosure, the thicknesses of the contact barrier layers 301b1-301b3 are 6 nm.

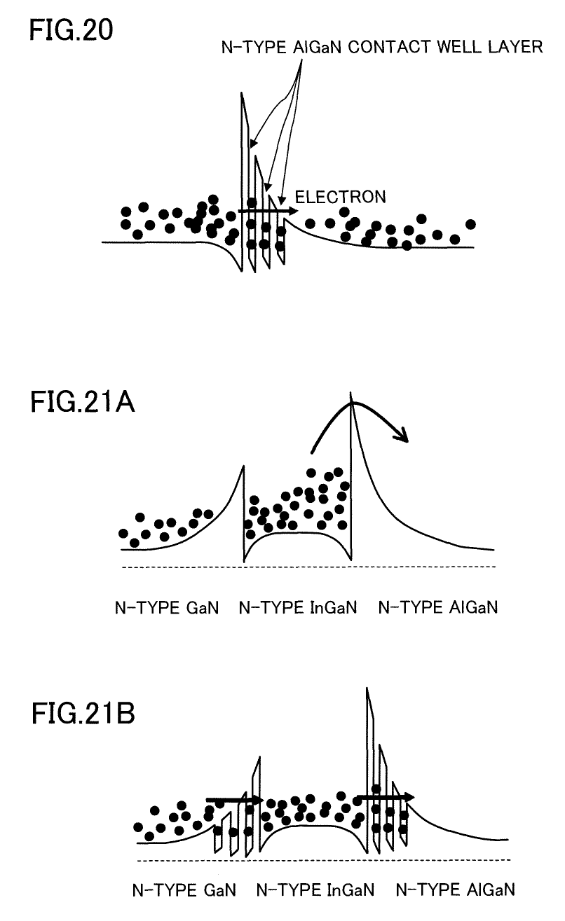

As described above, the nitride semiconductor laser also includes, between the n-type GaN substrate 300 and the n-type AlGaN cladding layer 312, the first quantum well heterobarrier layer 301 including the contact well layers 301w1-301w3 whose band gap energies gradually increase toward the n-type AlGaN cladding layer 312. As a result, a conduction band in the vicinity of the n-type GaN substrate 300 and the n-type AlGaN cladding layer 312 has a band structure as shown in FIG. 20. Therefore, electrons can be conducted from the n-type GaN substrate 300 to the n-type AlGaN cladding layer 312 even when a low bias voltage is applied.

The compositions and the band gap energies of the contact well layers 301w1-301w3 may be changed so that the band gap energies gradually increase and the thicknesses gradually decrease toward the n-type AlGaN cladding layer 312. Specifically, the thicknesses of the AlGaN contact well layers 301w1-301w3 are 6 nm, 4 nm, and 2 nm, and the Al mole fractions of the AlGaN contact well layers 301w1-301w3 are 0.02, 0.05, and 0.08, in order of distance from the n-type GaN substrate 300 (closest first). As a result, the energies at the ground-state quantum level of electrons existing in the contact well layers 301w1-301w3 can gradually approach the AlGaN conduction band edge energy, i.e., the closer the contact well layer is to the n-type AlGaN cladding layer 312, the closer the energy at the ground-state quantum level of electrons existing in the contact well layer is to the AlGaN conduction band edge energy. As a result, electrons injected from the n-type GaN substrate 300 can efficiently exist at a quantum level closest to the AlGaN conduction band edge energy in the contact well layer 301w1, whereby the operating voltage can be further reduced.

While, in the second embodiment of the present disclosure, only the example in which the n-type cladding layer is made of AlGaN has been described, the cladding layer, the contact well layer, and the contact barrier layer may be made of AlGaInN. In this case, the contact well layer may be made of an AlGaInN material whose band gap energy is smaller than that of the n-type cladding layer, and the contact barrier layer may be made of an AlGaInN material whose band gap energy is smaller than or equal to that of the cladding layer and greater than that of the contact well layer, whereby similar advantages can be obtained.

By adjusting the composition of the contact barrier layer so that tensile strain occurs therein, the band gap energy of the contact barrier layer is increased. Therefore, the magnitude of the energy at a quantum level formed in the contact well layer can be increased. As a result, electrons can pass through heterospikes at the interface between the contact barrier layer and the intermediate layer even when a lower bias voltage is applied, whereby the operating voltage can be further reduced.

While, in the second embodiment of the present disclosure, the example in which the quantum well heterobarrier layer is formed on the n-type GaN substrate has been described, an n-type GaN contact layer may be formed on the n-type GaN substrate, and the quantum well heterobarrier intermediate layer may be formed on the n-type GaN contact layer. In this case, similar advantages can be obtained.

### Third Embodiment

Next, a semiconductor laser device according to a third embodiment of the present disclosure will be described.

Firstly, in the case of nitride blue-violet lasers, the GaN layer and the AlGaN layer are transparent to laser oscillation light emitted from the active layer made of InGaN materials. Therefore, scattered light in the waveguide is reflected by the electrode to be fed back to the waveguide, so that the intensity of emitted light fluctuates, and therefore, the level of noise increases. Moreover, the scattered light interferes with laser light emitted from the facet, leading to a disturbance in the FFP of the emitted laser light. When the blue-violet laser is used as a light source for an optical disk system, the increase of the noise level leads to a reduction in the quality of information which is recorded or reproduced to or from an optical disk, and the disturbance of the FFP leads to a reduction in the efficiency of use of emitted laser light in the optical system of an optical pickup system. As a result, a serious problem will arise in actual use. To reduce or prevent this problem, a light absorption layer which absorbs laser oscillation light may be provided between the substrate and the n-type cladding layer, whereby laser light is absorbed by the light absorption layer. Therefore, it is possible to reduce or prevent the feedback of scattered light in the waveguide after being reflected by the n-type electrode having a large area, whereby the increase of the noise level and the disturbance of the FFP can be reduced or prevented.

However, when the light absorption layer is simply provided, as shown in a conduction band structure diagram of FIG. 21A an extra voltage is required in order to inject electrons injected from the N-type GaN layer into the n-type AlGaN layer because of spikes formed at two interfaces between the light absorption layer, and the n-type AlGaN cladding layer and the n-type GaN layer, leading to an increase in the operating voltage. For example, when the In mole fraction of the InGaN light absorption layer is 0.2, and the Al mole fraction of the n-type AlGaN cladding layer is 0.1, ΔE_{c} increases from 0.13 eV (where the light absorption layer is not provided) to 0.67 eV. Also, ΔE_{c} at the interface between the n-type GaN layer and the InGaN light absorption layer increases to 0.544 eV.

As a result, in the case of semiconductor lasers made of nitride materials, if a light absorption layer is provided near the n-type cladding layer, the disturbance of the FFP and the increase of the noise level can be reduced, however, the operating voltage disadvantageously increases.

Therefore, the laser device of the third embodiment of the present disclosure includes, at an interface between a first cladding layer of a first conductivity type and a substrate of the first conductivity type, a quantum well heterobarrier intermediate layer having a multilayer structure including well layers whose band gap energies gradually increase toward the first cladding layer of the first conductivity type (i.e., the band gap energy of each well layer is greater than the band gap energies of those farther away from the first cladding layer). As a result, even when it is made of nitride materials, the semiconductor laser can perform high-power operation at a low voltage (see FIG. 21B).

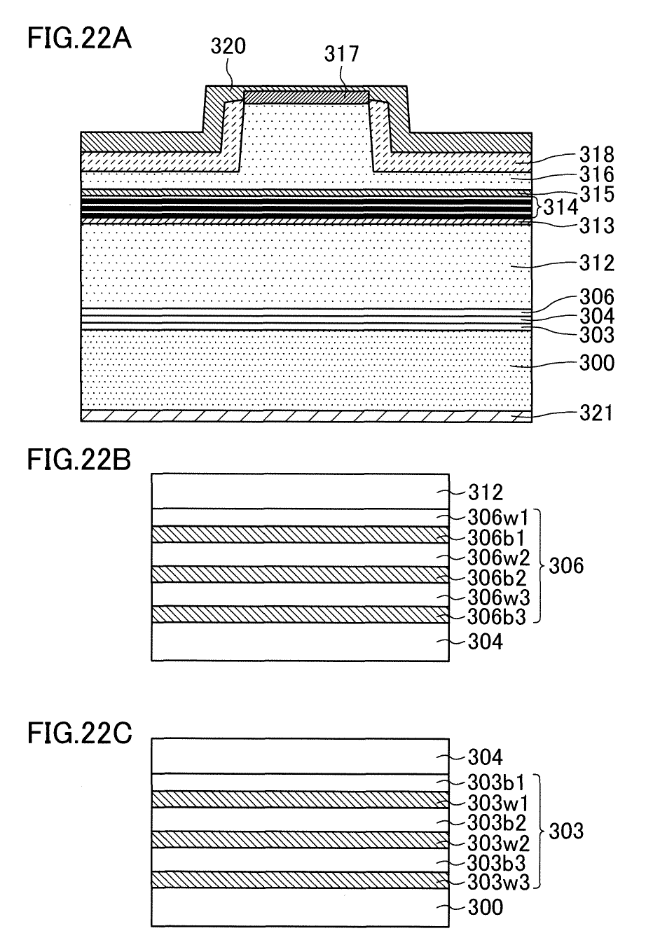

FIG. 22A is a diagram showing a cross-sectional structure of the semiconductor laser device of the third embodiment of the present disclosure.

As shown in FIG. 22A, on a GaN substrate 300, formed are an n-type second quantum well heterobarrier layer 303 (see FIG. 22C), an n-type InGaN first contact layer 304 having an ability to absorb light, an n-type first quantum well heterobarrier layer 306 (see FIG. 22B), an AlGaN cladding layer (thickness: 2.5 μm) 312, an n-type AlGaN guide layer (thickness: 86 nm) 313, an InGaN quantum well active layer 314, a p-type AlGaN electron blocking layer (thickness: 10 nm) 315, a p-type AlGaN cladding layer 316, a p-type GaN contact layer (thickness: 0.1 μm) 317, a first current blocking layer 318 transparent to a distribution of light, a p-type electrode 320, and an n-type electrode 321. The ridge has a width (W) of 1.4 μm.

Here, it is assumed that the distance between an upper portion of the ridge of the p-type AlGaN cladding layer 316 and the active layer 314 is 0.5 μm, and the distance between a lower end portion of the ridge and the active layer 314 is dP (0.1 μm).

In this structure, light emitted from the quantum well active layer 314 is absorbed and removed by the light absorptive first contact layer 304, and therefore, it is possible to reduce or prevent reentering into the quantum well active layer 314 of laser light reflected by the n-type electrode 321 and spontaneous emission light, which causes a disturbance in the FFP or an increase in the noise level of light output. In this embodiment, the first contact layer is made of InGaN with an In mole fraction of 0.2 to have an ability to absorb laser oscillation light of the 405-nm band from the active layer 314. Because the light absorption layer with a smaller thickness has a lower light absorption effect, the thickness of the light absorption layer needs to be at least 10 nm. If the thickness of the light absorption layer is excessively increased, a lattice mismatch occurs between the light absorption layer and the GaN substrate, resulting in a lattice defect. Therefore, the thickness of the light absorption layer needs to be 30 nm or less. In this embodiment, the thickness of the first contact layer 304 is set to 20 nm, whereby the light absorption effect and the reduction or prevention of the lattice defect are simultaneously achieved.

Here, a structure of the first quantum well heterobarrier layer 306 will be described.

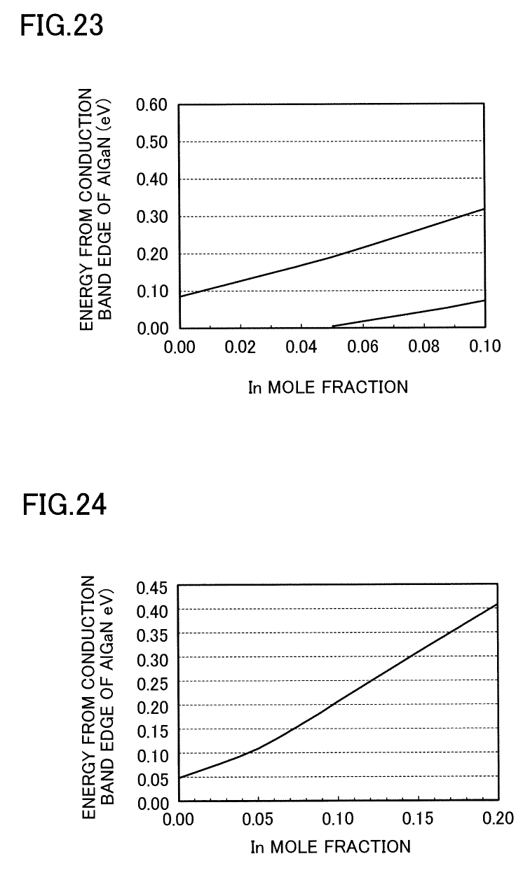

FIG. 23 shows the result of calculation of the energy levels of electrons formed in the contact well layers 306w1-306w3, which are obtained when the In mole fractions of the contact well layers 306w1-306w3 are changed from 0 to 0.1, where the Al mole fraction of the n-type AlGaN cladding layer 312 is 0.1, the contact barrier layers 306b1-306b3 are made of AlGaN having an Al mole fraction of 0.1, and the contact well layers 306w1-306w3 are an InGaN layer having a thickness of 4 nm. Note that the calculation result shows differences in quantum level energy as measured from the conduction band edges of the AlGaN contact barrier layers 306b1-306b3.

As can be seen from the calculation result of FIG. 23, if the In mole fractions of the contact well layers 306w1-306w3 are set to 0.1, 0.055, and 0.01, which gradually decrease toward the n-type AlGaN cladding layer 312, the energy levels of ground-state electrons formed in the contact well layers 306w1-306w3 can be set to 0.32 eV, 0.20 eV, and 0.10 eV, which gradually approach the conduction band edge of the n-type AlGaN cladding layer 312 (these values are spaced a small interval (about 0.1 eV) apart), where these values are measured from the conduction band edge of the n-type AlGaN cladding layer 312. Therefore, the energy level of electrons injected from the n-type first contact layer 304 toward the n-type AlGaN cladding layer 312 efficiently increases as the electrons approach the n-type AlGaN cladding layer 312 before reaching the n-type AlGaN cladding layer 312 via the first quantum well heterobarrier layer 306. As a result, the increase of the operating voltage can be reduced or prevented.

Next, FIG. 24 shows the result of calculation of the energy levels of electrons found in the contact well layers 306w1-306w3, which are obtained when the In mole fractions of the contact well layers 306w1-306w3 are changed from 0 to 0.2, where the Al mole fraction of the n-type AlGaN cladding layer 312 is 0.1, the contact barrier layers 306b1-306b3 are made of AlGaN having an Al mole fraction of 0.1, and the contact well layers 306w1-306w3 are an InGaN layer having a thickness of as small as 2 nm Note that the calculation result shows differences in quantum level energy as measured from the conduction band edges of the AlGaN contact barrier layers 306b1-306b3.

As can be seen from the calculation result of FIG. 24, if the In mole fractions of the contact well layers 306w1-306w3 are set to 0.15, 0.07, and 0.01, which gradually decrease toward the n-type AlGaN cladding layer 312, the energy levels of ground-state electrons formed in the contact well layers 306w1-306w3 can be set to 0.32 eV, 0.15 eV, and 0.06 eV, which gradually approach the conduction band edge of the n-type AlGaN cladding layer 312 (these values are spaced a small interval (about 0.1 eV) apart), where these values are measured from the conduction band edge of the n-type AlGaN cladding layer 312. Therefore, the energy level of electrons injected from the n-type first contact layer 304 toward the n-type AlGaN cladding layer 312 efficiently increases as the electrons approach the n-type AlGaN cladding layer 312 before reaching the n-type AlGaN cladding layer 312 via the first quantum well heterobarrier layer 306. As a result, the increase of the operating voltage can be reduced or prevented.

Here, the In mole fractions of the InGaN contact well layers 306w1-306w3 are preferably 0.15 or less. This is because if the In mole fraction is 0.15 or more, strain energy is accumulated in the InGaN crystal itself because InN and GaN have different interatomic spacings, and therefore, compositional separation is likely to occur. If compositional separation occurs, in-plane variations occur in the band gap energy of the contact well layer, and therefore, it is difficult to accurately control the quantum level energy of electrons in the contact well layer. Therefore, variations occur in the conduction of electrons, and therefore, it is difficult to obtain the desired effect that the energy of electrons increases as the electrons pass through one contact barrier layer due to the tunnel effect to reach the following contact well layer.

As can be seen from the calculation results of FIGS. 23 and 24, as the thicknesses of the contact well layers 306w1-306w3 are decreased, the quantum level energies of the contact well layers 306w1-306w3 approach the energies of the conduction bands of the contact barrier layers 306b1-306b3, where the In mole fractions of the contact well layers 306w1-306w3 are the same. When the In mole fractions of the contact well layers 306w1-306w3 are 0.1, and the Al mole fractions of the contact barrier layers 306b1-306b3 are 0.1, then if the thicknesses of the contact well layers 306w1-306w3 are decreased from 4 nm to 2 nm, the energy differences between the conduction bands of the contact barrier layers 306b1-306b3 and the ground-state quantum levels of the contact well layers 306w1-306w3 decrease from 0.32 eV to 0.2 eV. This means that as the thicknesses of the contact well layers 306w1-306w3 are decreased, the energies at the ground-state quantum level of the contact well layers 306w1-306w3 as measured from the conduction band energy of n-type InGaN are likely to increase. Therefore, if the thicknesses of the contact well layers 306w1-306w3 are excessively decreased, the probability that electrons from the n-type first contact layer 304 pass through the contact barrier layers 306b1-306b3 due to the tunnel effect to reach the contact well layers 306w1-306w3 decreases.

When interface layers form mixed crystal at the interfaces between the contact well layers 306w1-306w3 and the contact barrier layers 306b1-306b3, the average Al mole fractions of the contact well layers 306w1-306w3 increase, so that the ground-state quantum levels of the contact well layers 306w1-306w3 further increase. As a result, the tunneling probability of electrons is likely to further decrease.

Conversely, if the thicknesses of the contact well layers 306w1-306w3 are increased, the quantum level energies of electrons formed in the contact well layers 306w1-306w3 decrease, and therefore, the differences from the conduction band energies of the contact barrier layers 306b1-306b3 increase. Therefore, the probability that electrons efficiently exist at a high energy state, i.e., an energy level closest to the AlGaN conduction band edge energy, decreases. Therefore, the thicknesses of the contact well layers 306w1-306w3 need to be set to a value between 2 nm and 6 nm, inclusive. In this embodiment, as an example, the thicknesses of the contact well layers 306w1-306w3 are 2 nm. The In mole fractions of the contact well layers 306w1-306w3 are set to 0.15, 0.07, and 0.01, which gradually decrease toward the n-type AlGaN cladding layer 312.

In order to exhibit the tunnel effect in the contact barrier layers 306b1-306b3, the thicknesses of the contact barrier layers 306b1-306b3 need to be smaller than or equal to approximately the wavelength of an electron wave function, i.e., needs to be 8 nm or less. Note that if the thicknesses of the contact barrier layers 306b1-306b3 are excessively decreased, the quantum levels of the contact well layers 306w1-306w3 are strongly coupled to form minibands, so that the quantum level of electrons foil led in each of the contact well layers 306w1-306w3 is split, and therefore, the probability that electrons exist at a low energy state in the contact well layers 306w1-306w3 increases. Therefore, when electrons are conducted from the contact well layer 306w1 to the n-type AlGaN cladding layer 312, the proportion of electrons which are significantly affected by the heterobarrier still increases, and therefore, the operating voltage reduction effect is reduced. Therefore, in order to obtain a high tunneling probability and reduce or prevent the formation of minibands caused by the coupling of the quantum levels of electrons between the contact well layers 306w1-306w3, the thicknesses of the contact barrier layers 306b1-306b3 need to be set to a value between 2 nm and 8 nm, inclusive. In this embodiment, as an example, the thicknesses of the contact barrier layers 306b1-306b3 are 4 nm.

Next, a structure of the second quantum well heterobarrier layer 303 will be described.

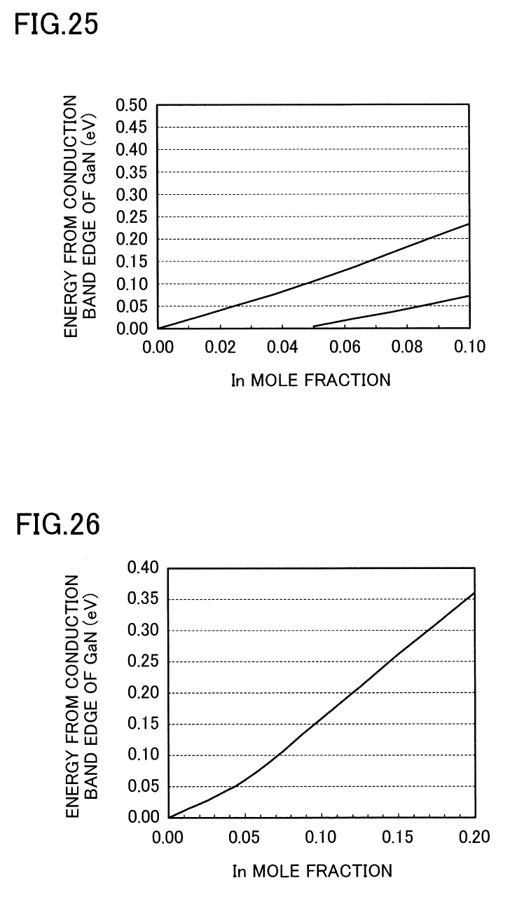

FIG. 25 shows the result of calculation of the energy levels of electrons formed in near-substrate contact well layers 303w1-303w3, which are obtained when the In mole fractions of the near-substrate contact well layers 303w1-303w3 are changed from 0 to 0.1, where near-substrate contact barrier layers 303b1-303b3 are made of GaN, and the near-substrate contact well layers 303w1-303w3 are an InGaN layer having a thickness of 4 nm. Note that the calculation result shows differences in quantum level energy as measured from the conduction band edges of the near-substrate GaN contact barrier layers 303b1-303b3.

As can be seen from the calculation result of FIG. 25, if the In mole fractions of the near-substrate contact well layers 303w1-303w3 are set to 0.1, 0.05, and 0.01, which gradually decrease toward the n-type GaN substrate 300, the energy levels of ground-state electrons formed in the near-substrate contact well layers 303w1-303w3 can be set to successively changing values, 0.24 eV, 0.10 eV, and 0.02 eV (these values are spaced a small interval (about 0.1 eV) apart), where these values are measured from the conduction band edge of n-type GaN. Therefore, even when the energy level of electrons injected from the n-type GaN substrate 300 toward the n-type first contact layer 304 is low, it is possible to increase the probability that the electrons reach the near-substrate contact well layer 303w3, and are conducted toward the near-substrate contact well layer 303w1 due to the tunnel effect. As a result, the increase of the operating voltage can be reduced or prevented.

Next, FIG. 26 shows the result of calculation of the energy levels of electrons formed in the near-substrate contact well layers 303w1-303w3, which are obtained when the In mole fractions of the near-substrate contact well layers 303w1-303w3 are changed from 0 to 0.2, where the near-substrate contact barrier layers 303b1-303b3 are made of GaN, and the near-substrate contact well layers 303w1-303w3 are an InGaN layer having a thickness of as small as 2 nm. Note that the calculation result shows differences in quantum level energy as measured from the conduction band edges of the near-substrate GaN contact barrier layers 303b1-303b3.

As can be seen from the calculation result of FIG. 26, if the In mole fractions of the near-substrate contact well layers 303w1-306w3 are set to 0.15, 0.08, and 0.02, which gradually decrease toward the n-type GaN substrate 300, the energy levels of ground-state electrons formed in the near-substrate contact well layers 303w1-303w3 can be set to successively changing values, 0.25 eV, 0.12 eV, and 0.02 eV (these values are spaced a small interval (about 0.1 eV) apart), where these values are measured from the conduction band edge of n-type GaN. Therefore, even when the energy level of electrons injected from the n-type GaN substrate 300 toward the n-type first contact layer 304 is low, it is possible to increase the probability that the electrons reach the near-substrate contact well layer 303w3, and are conducted toward the near-substrate contact well layer 303w1 due to the tunnel effect can be increased. As a result, the increase of the operating voltage can be reduced or prevented.

Here, the In mole fractions of the near-substrate InGaN contact well layers 303w1-303w3 are preferably 0.15 or less. This is because if the In mole fraction is 0.15 or more, strain energy is accumulated in the InGaN crystal itself because InN and GaN have different interatomic spacings, and therefore, compositional separation is likely to occur. If compositional separation occurs, in-plane variations occur in the band gap energies of the near-substrate contact well layers 303w1-303w3, and therefore, it is difficult to accurately control the quantum level energy of electrons in the near-substrate contact well layers 303w1-303w3. Therefore, variations occur in the conduction of electrons, and therefore, it is difficult to obtain the desired effect that the energy of electrons increases as the electrons pass through the near-substrate contact barrier layers 303b1-303b3 due to the tunnel effect to reach the following near-substrate contact well layers 303w1-303w3.

As can be seen from the calculation results of FIGS. 25 and 26, as the thicknesses of the near-substrate contact well layers 303w1-303w3 are decreased, the quantum level energies of the near-substrate contact well layers 303w1-303w3 approach the energies of the conduction bands of the near-substrate contact barrier layers 303b1-303b3, where the In mole fractions of the near-substrate contact well layers 303w1-303w3 are the same. When the In mole fractions of the near-substrate contact well layers 303w1-303w3 are 0.1, and the near-substrate contact barrier layers 303b1-303b3 are made of GaN, then if the thicknesses of the near-substrate contact well layers 303w1-303w3 are decreased from 4 nm to 2 nm, the energy differences between the conduction bands of the near-substrate contact barrier layers 303b1-303b3 and the ground-state quantum levels of the near-substrate contact well layers 303w1-303w3 decrease from 0.24 eV to 0.15 eV. This means that as the thicknesses of the near-substrate contact well layers 303w1-303w3 are decreased, the energies at the ground-state quantum level of the near-substrate contact well layers 303w1-303w3 as measured from the conduction band energy of n-type InGaN are likely to increase. Therefore, if the thicknesses of the near-substrate contact well layers 303w1-303w3 are excessively decreased, the probability that electrons from the n-type GaN substrate 300 pass through the near-substrate contact barrier layers 303b3-303b1 due to the tunnel effect to reach the near-substrate contact well layer 303w1 decreases.

When interface layers form mixed crystal at the interfaces between the near-substrate contact well layers 303w1-303w3 and the near-substrate contact barrier layers 303b1-303b3, the average Ga mole fractions of the near-substrate contact well layers 303w1-303w3 increase, so that the ground-state quantum levels of the near-substrate contact well layers 303w1-303w3 further increase. As a result, the tunneling probability of electrons is likely to further decrease.

Conversely, if the thicknesses of the near-substrate contact well layers 303w1-303w3 are increased, the quantum level energies of electrons formed in the near-substrate contact well layers 303w1-303w3 decrease, and therefore, the differences from the conduction band energies of the near-substrate contact barrier layers 303b1-303b3 increase. Therefore, the probability that electrons efficiently exist at a high energy state, i.e., an energy level closest to the GaN conduction band edge energy, decreases. Therefore, the thicknesses of the near-substrate contact well layers 303w1-303w3 need to be set to a value between 2 nm and 6 nm, inclusive. In this embodiment, as an example, the thicknesses of the near-substrate contact well layers 303w1-303w3 are 2 nm. The In mole fractions of the near-substrate contact well layers 303w1-303w3 are set to 0.02, 0.08, and 0.15, which gradually decrease toward the n-type first contact layer 304.

In order to exhibit the tunnel effect in the near-substrate contact barrier layers 303b1-303b3, the thicknesses of the near-substrate contact barrier layers 303b1-303b3 need to be smaller than or equal to approximately the wavelength of an electron wave function, i.e., needs to be 8 nm or less. Note that if the thicknesses of the near-substrate contact barrier layers 303b1-303b3 are excessively decreased, the quantum levels of the near-substrate contact well layers 303w1-303w3 are strongly coupled to form minibands, so that the quantum level of electrons formed in each of the near-substrate contact well layers 303w1-303w3 is split, and therefore, the probability that electrons exist at a low energy state in the near-substrate contact well layers 303w1-303w3 increases. Therefore, when electrons are conducted from the contact well layer 306w1 to the n-type AlGaN cladding layer 312, the proportion of electrons which are significantly affected by the heterobarrier still increases, and therefore, the operating voltage reduction effect is reduced. Therefore, in order to obtain a high tunneling probability and reduce or prevent the formation of minibands caused by the coupling of the quantum levels of electrons between the near-substrate contact well layers 303w1-303w3, the thicknesses of the near-substrate contact barrier layers 303b1-303b3 need to be set to a value between 2 nm and 8 nm, inclusive. In this embodiment, as an example, the thicknesses of the near-substrate contact barrier layers 303b1-303b3 are 4 nm.

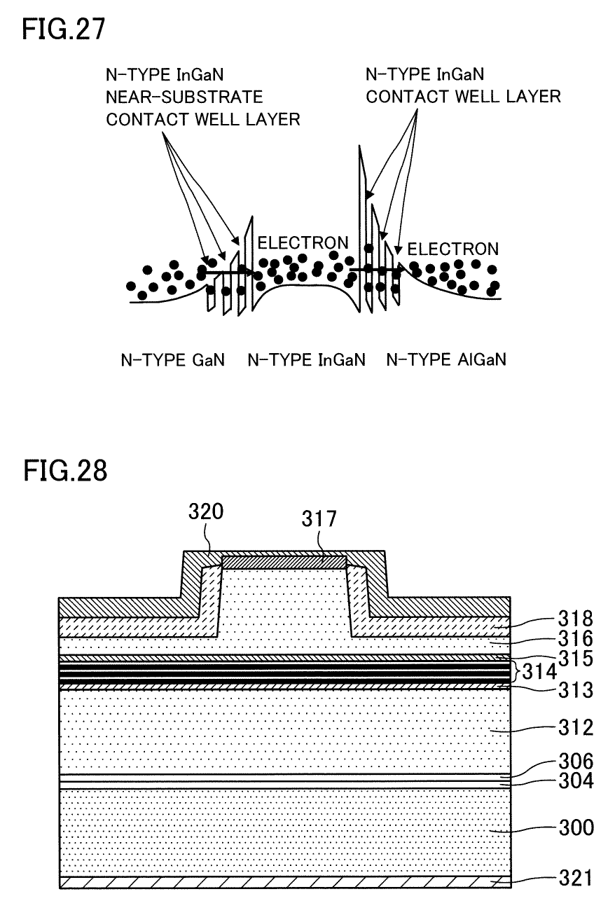

As described above, the semiconductor laser device of this embodiment includes the first quantum well heterobarrier layer 306 including the contact well layers 306w1-306w3 whose band gap energies gradually increase toward the n-type AlGaN cladding layer 312, between the n-type the first contact layer 304 and the n-type AlGaN cladding layer 312, and the second quantum well heterobarrier layer 303 including the near-substrate contact well layers 303w1-303w3 whose band gap energies gradually decrease toward n-type the first contact layer 304, between the n-type GaN substrate 300 and the n-type the first contact layer 304. As a result, even in the case of a nitride semiconductor laser including a light absorptive first contact layer between the substrate and the n-type cladding layer, a conduction band in the vicinity of the n-type GaN substrate 300 and the n-type AlGaN cladding layer 312 has a band structure as shown in FIG. 27. Therefore, electrons can be conducted from the n-type GaN substrate to the n-type cladding layer even when a low bias voltage is applied.

The compositions and the band gap energies of the contact well layers 306w1-306w3 may be changed so that the band gap energies gradually increase and the thicknesses gradually decrease toward the n-type AlGaN cladding layer 312. Specifically, the thicknesses of the InGaN contact well layers 306w1-306w3 may be set to 6 nm, 4 nm, and 2 nm, and the In mole fractions of the InGaN contact well layers 306w1-306w3 may be set to 0.1, 0.055, and 0.01. As a result, the energies at the ground-state quantum level of electrons existing in the near-substrate contact well layers 306w1-306w3 can gradually approach the AlGaN conduction band edge energy, i.e., the closer the contact well layer is to the n-type AlGaN cladding layer 312, the closer the energy at the ground-state quantum level of electrons existing in the contact well layer is to the AlGaN conduction band edge energy. As a result, electrons injected from the n-type first contact layer 304 can efficiently exist at a quantum level closest to the AlGaN conduction band edge energy in the contact well layer 306w1, whereby the operating voltage can be further reduced.

The compositions and the band gap energies of the near-substrate contact well layers 303w1-303w3 may be changed so that the band gap energies gradually increase and the thicknesses gradually decrease toward the n-type first contact layer 304. Specifically, the thicknesses of the near-substrate InGaN contact well layers 303w1-303w3 may be set to 2 nm, 4 nm, and 6 nm, and the In mole fractions of the InGaN contact well layers 303w1-303w3 may be set to 0.01, 0.055, and 0.1. As a result, the energies at the ground-state quantum level of electrons existing in the near-substrate contact well layers 303w1-303w3 can gradually approach the conduction band edge energy of the n-type first contact layer 304, i.e., the closer the contact well layer is to the n-type first contact layer 304, the closer the energy at the ground-state quantum level of electrons existing in the contact well layer is to the conduction band edge energy of the n-type first contact layer 304. As a result, electrons injected from the n-type substrate 300 can efficiently exist at a quantum level closest to the conduction band edge energy of the first contact layer 304 in the contact well layer 303w1, whereby the operating voltage can be further reduced.

While, in this embodiment, only the example in which the n-type cladding layer 312 is made of AlGaN has been described, the n-type cladding layer 312 may be made of AlGaInN. While only the example in which the contact barrier layers 306b1-306b3 are made of AlGaN has been described, the contact barrier layers 306b1-306b3 may be made of AlGaInN. While only the example in which the near-substrate contact barrier layers 303w1-303w3 are made of GaN has been described, the near-substrate contact barrier layers 303w1-303w3 may be made of AlGaInN. While only the example in which the contact well layers 306w1-306w3 and the near-substrate contact well layers 303w1-303w3 are made of InGaN has been described, the contact barrier layers 306b1-306b3 and the near-substrate contact barrier layers 303b1-303b3 may be made of AlGaInN.

In this case, the contact well layers 306w1-306w3 may be made of an AlGaInN material having a smaller band gap energy than that of the n-type cladding layer 312, and the contact barrier layers 306b1-306b3 may be made of an AlGaInN material having a band gap energy smaller than or equal to that of the n-type cladding layer 312 and greater than that of the contact well layers 306w1-306w3, whereby similar advantages can be obtained.

Moreover, if the contact barrier layers 306b1-306b3 and the near-substrate contact barrier layers 303b1-303b3 are made of a composition which causes tensile strain, the band gap energies of the contact barrier layers 306b1-306b3 and the near-substrate contact barrier layers 303b1-303b3 increase. Therefore, the magnitudes of energies at quantum levels formed in the contact well layers 306w1-306w3 can be increased. Therefore, electrons can pass through heterospikes formed at the interface with the first contact layer 304 even at a lower bias voltage, whereby the operating voltage can be further reduced.

While, in this embodiment, the example in which the second quantum well heterobarrier intermediate layer 303 is formed on the n-type GaN substrate 300 has been described, an n-type GaN first contact layer 304 may be found on the n-type GaN substrate 300, and the quantum well heterobarrier layer intermediate layer 303 may be formed on the n-type GaN first contact layer 304. In this case, advantages similar to those described above can be obtained.

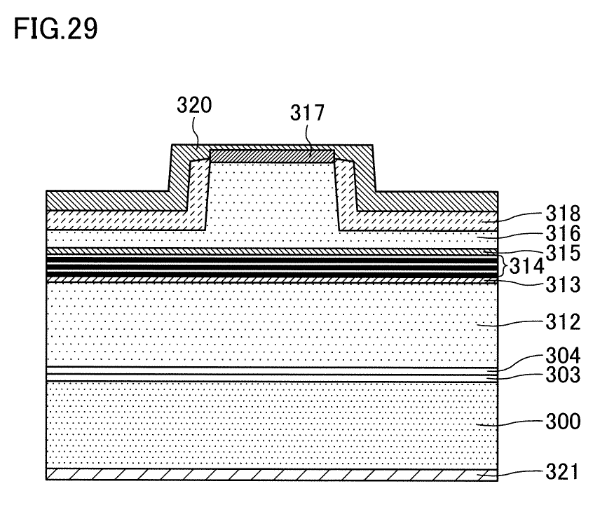

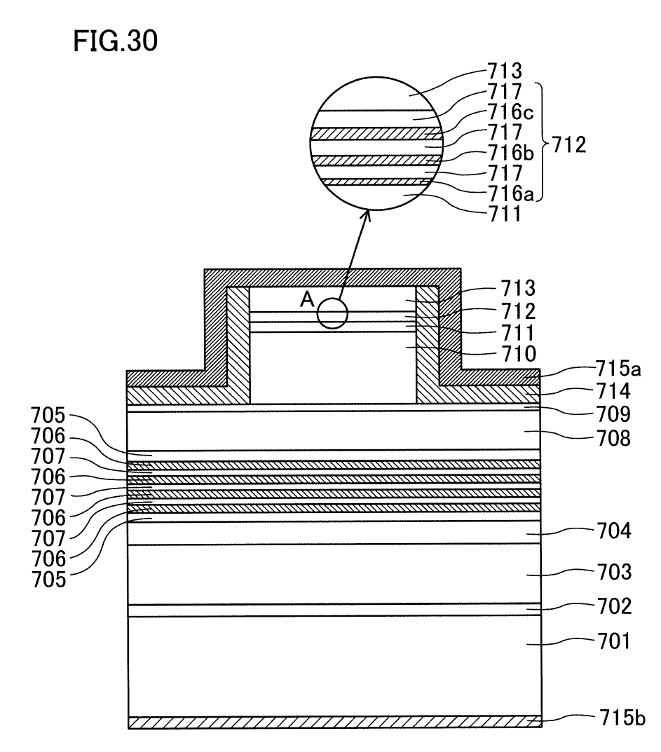

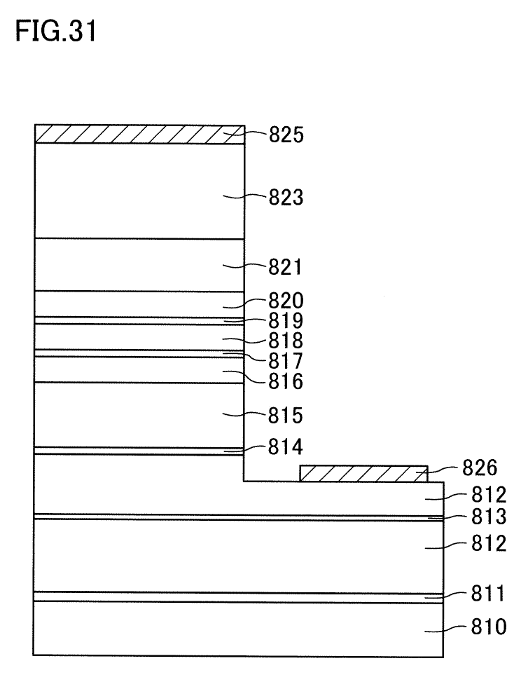

In this embodiment, the example in which the quantum well heterobarrier intermediate layers 303 and 306 are provided on the opposite sides of the first contact layer 304 (the layer 303 is closer to the substrate while the layer 306 is closer to the n-type cladding layer) has been described. Alternatively, as shown in FIGS. 28 and 29, a quantum well heterobarrier intermediate layer may be provided only on one (closer to either the substrate or the n-type cladding layer) of the opposite sides of the first contact layer 304. Also in this case, the disturbance of the FFP and the noise level of light output can be reduced, and the operating voltage can be reduced.

In the first to third embodiments, the example in which the first quantum well heterobarrier layer has a structure of a cladding layer/a contact well layer/a contact barrier layer/a contact well layer/a contact barrier layer/a contact well layer/a contact barrier layer/a first contact layer, has been described. Alternatively, the first quantum well heterobarrier layer may have a structure of a cladding layer/a contact barrier layer/a contact well layer/a contact barrier layer/a contact well layer/a contact barrier layer/a contact well layer/a contact barrier layer/a first contact layer. In this case, similar advantages can be obtained.

The example in which the second quantum well heterobarrier layer has a structure of a substrate/a contact well layer/a contact barrier layer/a contact well layer/a contact barrier layer/a contact well layer/a contact barrier layer/a first contact layer, has been described above. Alternatively, the second quantum well heterobarrier layer may have a structure of a substrate/a contact barrier layer/a contact well layer/a contact barrier layer/a contact well layer/a contact barrier layer/a contact well layer/a contact barrier layer/a first contact layer. In this case, advantages similar to those described above can be obtained.

In the first to third embodiments of the present disclosure, the example in which there are three contact well layers and three near-substrate contact well layers has been described. Alternatively, the first and second quantum well heterobarrier intermediate layers may be formed so that the total thicknesses of the first and second quantum well heterobarrier intermediate layers fall within the range which does not exceed the thicknesses (typically 0.1 μm or less) of interfaces (at which heterospikes exist) between the first contact layer, and the cladding layer and the substrate, which are obtained when the quantum well heterobarrier intermediate layer is not provided. As a result, electrons are conducted through heterospikes due to the tunnel effect, whereby the operating voltage can be reduced.

In the first to third embodiments of the present disclosure, the example in which the quantum well heterobarrier layer is provided only in the n-type semiconductor layer in order to reduce or prevent the increase of the operating voltage caused by heterospikes formed at the interface of the n-type contact layer and the n-type cladding layer, has been described. Moreover, of course, a p-type quantum well heterobarrier layer may be additionally provided between the p-type contact layer and the p-type cladding layer, whereby the operating voltage can be further reduced.

Note that the aforementioned embodiments of the present disclosure may be applied to semiconductor devices, such as light emitting diodes etc., in addition to semiconductor laser devices. In this case, of course, similar advantages can be obtained.

The present disclosure is useful for structures of semiconductor laser devices which allow high-power operation at a low operating voltage.

What is claimed is:

1. A semiconductor light emitting device comprising:
a first cladding layer which is a semiconductor layer of a first conductivity type formed on a semiconductor substrate of the first conductivity type;
an active layer formed on the first cladding layer;
a second cladding layer which is a semiconductor layer of a second conductivity type formed on the active layer; and
an intermediate layer formed between the first cladding layer and the substrate and including a barrier layer of the first conductivity type and two or more well layers of the first conductivity type,
wherein
a forbidden band energy of the first cladding layer and forbidden band energies of the well layers satisfy a relationship represented by:
E1>E2
where E1 is the forbidden band energy of the first cladding layer, and E2 is the forbidden band energy of one of the well layers, and
the forbidden band energy of one of the well layers closer to the first cladding layer is greater than the forbidden band energy of one of the well layers closer to the substrate.

2. The semiconductor light emitting device of claim 1, wherein
the forbidden band energies of the well layers monotonically increase from the substrate toward the first cladding layer.

3. The semiconductor light emitting device of claim 1, wherein
a forbidden band energy of the barrier layer and forbidden band energies of the well layers satisfy a relationship represented by:
E1≧Ec1>Ec2≧E2
where Ec1 is the forbidden band energy of the barrier layer, and Ec2 is the forbidden band energy of another of the well layers.

4. The semiconductor light emitting device of claim 1, wherein
thicknesses of the well layers monotonically decrease from the substrate toward the first cladding layer.

5. The semiconductor light emitting device of claim 1, wherein
a lattice constant of the barrier layer is smaller than a lattice constant of the semiconductor substrate.

6. The semiconductor light emitting device of claim 1, wherein
a lattice constant of the barrier layer is smaller than a lattice constant of one of the first and second cladding layers which is closer to the barrier layer.

7. A semiconductor light emitting device comprising:
a first cladding layer formed on a GaAs substrate of a first conductivity type and made of AlGaInP of the first conductivity type;
an active layer formed on the first cladding layer;
a second cladding layer formed on the active layer and made of AlGaInP of a second conductivity type; and
an intermediate layer formed between the first cladding layer and the GaAs substrate and having a multilayer structure including an (AlₓGa₁₋ₓ)_{y}In_{1-y}P barrier layer, where 0≦x≦1 and 0<y<1, and two or more Al_{y}Ga_{1-y}As well layers, where 0≦y<1,
wherein
the Al mole fractions y of the well layers monotonically increase from the GaAs substrate toward the first cladding layer.

8. The semiconductor light emitting device of claim 7, wherein
one of the well layers closest to the GaAs substrate has an Al mole fraction between 0 and 0.1, inclusive, and
one of the well layers closest to the first cladding layer has an Al mole fraction between 0.2 and 0.3, inclusive.

9. The semiconductor light emitting device of claim 7, wherein
the well layers have a thickness between 2 nm and 6 nm, inclusive, and
the barrier layer has a thickness between 2 nm and 8 nm, inclusive.

10. The semiconductor light emitting device of claim 7, wherein
a lattice constant of the barrier layer is smaller than a lattice constant of the GaAs substrate.

11. A semiconductor light emitting device comprising:
a first cladding layer formed on a GaN substrate of a first conductivity type and made of an AlGaInN material of the first conductivity type;
an active layer formed on the first cladding layer;
a second cladding layer formed on the active layer and made of an AlGaInN material of a second conductivity type; and
a first quantum well heterobarrier intermediate layer formed between the first cladding layer and the substrate and having a multilayer structure including an Al_{xc}Ga_{yc}In_{1-xc-yc}N barrier layer, where 0≦xc<1, 0<yc≦1, and 0≦1−xc−yc<1, and two or more Al_{xw}Ga_{yw}In_{1-xw-yw}N well layers, where 0≦xw<1, 0<yw≦1, and 0≦1−xw−yw<1,
wherein
forbidden band energies of the well layers monotonically increase from the GaN substrate toward the first cladding layer.

12. The semiconductor light emitting device of claim 11, further comprising:
a first contact layer formed between the GaN substrate and the first quantum well heterobarrier intermediate layer,
wherein
a forbidden band energy of the first contact layer is smaller than a forbidden band energy of the active layer.

13. The semiconductor light emitting device of claim 12, further comprising:
a second quantum well heterobarrier intermediate layer formed between the GaN substrate and the first contact layer and having a multilayer structure including an AlₓₛGa_{ys}In_{1-xs-ys}N near-substrate barrier layer, where 0≦xs<1, 0<ys≦1, and 0≦1−xs−ys<1, and two or more Al_{xws}Ga_{yws}In_{1-xws-yws}N near-substrate well layers, where 0≦xws<1, 0<yws≦1, and 0≦1−xws−yws<1,
wherein
forbidden band energies of the near-substrate well layers monotonically increase from the first contact layer toward the GaN substrate.

14. The semiconductor light emitting device of claim 11, wherein
the near-substrate well layers and the well layers have a thickness between 2 nm and 6 nm, inclusive, and
the near-substrate barrier layer and the barrier layer have a thickness between 2 nm and 8 nm, inclusive.

15. The semiconductor light emitting device of claim 11, wherein
a lattice constant of the Al_{xc}Ga_{yc}In_{1-xc-yc}N barrier layer is smaller than a lattice constant of the GaN substrate.

16. The semiconductor light emitting device of claim 13, wherein
a lattice constant of the AlₓₛGa_{ys}In_{1-xs-ys}N near-substrate barrier layer is smaller than a lattice constant of the GaN substrate.
